(19) United States
(12) Patent Application Publication
(10) Pub. No.: US 2017/0290148 A1
(43) Pub. Date: Oct. 5, 2017

(54) METHOD FOR PRODUCING PRINTED WIRING BOARD

(71) Applicant: AJINOMOTO CO., INC., Tokyo (JP)

(72) Inventors: Masanori OHKOSHI, Kawasaki-shi (JP); Hirohisa NARAHASHI, Kawasaki-shi (JP)

(73) Assignee: AJINOMOTO CO., INC., Tokyo (JP)

(21) Appl. No.: 15/471,588

(22) Filed: Mar. 28, 2017

(30) Foreign Application Priority Data
Mar. 29, 2016 (JP) 2016-066252

(51) Int. Cl. H05K 1/03; B32B 37/06; B32B 7/12; H05K 3/00; H01L 23/498; H01L 23/00; H05K 3/38; B32B 37/12; H01L 21/48

(52) U.S. Cl. CPC H05K 1/036; B32B 37/12; B32B 37/06; B32B 7/12; H01L 21/4857; H01L 23/49822; H01L 23/49838; H01L 24/16; H01L 24/24; H01L 24/32; H01L 24/48; H05K 3/388; H05K 3/0058; B32B 2457/08; B32B 2309/02; H01L 2224/16227; H01L 2224/24227; H01L 2224/32227; H01L 2224/48227

(57) ABSTRACT

Printed wiring boards with reduced curing unevenness and the like may be produced by (A) preparing an adhesive sheet having a support and a resin composition layer provided on the support, (B) laminating the adhesive sheet on an internal layer substrate so that the resin composition layer is in contact with the internal layer substrate, and (C) thermally curing the adhesive sheet by heating from T1 (° C.) to T2 (° C.), to form an insulating layer, wherein the adhesive sheet is thermally cured so that a relation of Y>2700X is satisfied in which X is the sum of a difference between a maximum expansion rate of the support in the MD direction during heating from T1 (° C.) to T2 (° C.) and an expansion rate of the support at the end of heating and a difference between a maximum expansion rate of the support in the TD direction during heating from T1 (° C.) to T2 (° C.) and an expansion rate of the support at the end of heating and Y is the lowest melt viscosity of the resin composition layer at 120° C. or higher.

### CROSS REFERENCES TO RELATED APPLICATIONS

This application claims priority to Japanese Patent Application No. 2016-066252, filed on Mar. 29, 2016, which is incorporated herein by reference in its entirety.

### BACKGROUND OF THE INVENTION

### Field of the Invention

The present invention relates to methods for producing a printed wiring board. The present invention also relates to adhesive sheets and layered bodies used in such a method. The present invention further relates to semiconductor devices provided with a printed wiring board produced by such a method.

### Discussion of the Background

As a method for producing a printed wiring board, there is known a production method using a build-up process of alternately layering an insulating layer and a conductive layer. In the production method using the build-up process, the insulating layer is generally formed by thermally curing a resin composition. A multi-layered printed wiring board is provided with a plurality of build-up layers that are formed through the build-up process. In addition to further microfabrication and higher densification of wirings, the insulating layer is required to have excellent peel strength to the conductive layer.

As for such an insulating layer, for example, JP-A-2015-162635, which is incorporated herein by reference in its entirety, discloses a method for producing a printed wiring board in which an adhesive sheet containing a support that exhibits particular expansion characteristics during heating is used and the support is removed after thermal curing.

However there remains a need for improved processes for preparing printed wiring board.

### SUMMARY OF THE INVENTION

The present inventors have found the following matters. That is, in a method for producing a printed wiring board that includes bonding an adhesive sheet to an internal layer substrate and removing a support after thermal curing, the support expands or contracts during thermal curing, which in turn causes expansion or contraction of a resin composition layer. As a result, curing of a surface of the resin composition layer is made uneven and the thickness of the resin composition layer is made uneven (undulation occurs). Thus, a yield of the printed wiring board is decreased.

Accordingly, it is one object of the present invention to provide novel methods for producing a printed wiring board.

It is another object of the present invention to provide novel method for producing a printed wiring board that suppresses occurrence of curing unevenness and undulation even when a resin composition layer with a support attached thereto is thermally cured to form an insulating layer.

It is another object of the present invention to provide novel adhesive sheets which are used in such a method.

It is another object of the present invention to provide novel layered bodies which are used in such a method.

It is another object of the present invention to provide novel semiconductor device which contain such a printed wiring board.

These and other objects, which will become apparent during the following detailed description, have been achieved by the inventors' discovery that the occurrence of curing unevenness and undulation can be suppressed by the following configuration.

Specifically, the present invention includes the following embodiments.

(1) A method for producing a printed wiring board, comprising the steps of:

(A) preparing an adhesive sheet including a support and a resin composition layer provided on the support;

(B) laminating the adhesive sheet on an internal layer substrate so that the resin composition layer is in contact with the internal layer substrate; and

(C) thermally curing the adhesive sheet by heating from T1 (° C.) to T2 (′C), to form an insulating layer, wherein

the thermal curing is performed so as to satisfy a relation of Y>2700X, in which X is a sum ((E_{AMD}−E_{BMD})+(E_{ATD}−E_{BTD})) of a difference (E_{AMD}−E_{BMD}) between a maximum expansion rate E_{AMD} (%) of the support in an MD direction during heating from T1 (° C.) to T2 (° C.) and an expansion rate E_{BMD} (%) of the support at T2 (° C.) at the end of heating and a difference (E_{ATD}−E_{BTD}) between a maximum expansion rate E_{ATD} (%) of the support in a TD direction during heating from T1 (° C.) to T2 (° C.) and an expansion rate E_{BTD} (%) of the support at T2 (° C.) at the end of heating, and Y is a lowest melt viscosity (poise) of the resin composition layer at 120° C. or higher.

(2) The method for producing a printed wiring board according to (1), wherein the printed wiring board satisfies a relation of Y>2700X>300.

(3) The method for producing a printed wiring board according to (1) or (2), wherein X is 4 or less.

(4) The method for producing a printed wiring board according to any one of (1) to (3), wherein Y is 4,000 poises or more.

(5) A method for producing a printed wiring board, comprising the steps of:

(A) preparing an adhesive sheet including a support and a resin composition layer provided on the support;

(B) laminating the adhesive sheet on an internal layer substrate so that the resin composition layer is in contact with the internal layer substrate; and

(C) thermally curing the adhesive sheet by heating from T1 (° C.) to T2 (° C.), to form an insulating layer, wherein
the adhesive sheet is thermally cured so that a sum ((E_{AMD}−E_{BMD})+(E_{ATD}−E_{BTD})) of a difference (E_{AMD}−E_{BMD}) between a maximum expansion rate E_{AMD} (%) of the support in an MD direction during heating from T1 (° C.) to T2 (° C.) and an expansion rate E_{BMD} (%) of the support at T2 (° C.) at the end of heating and a difference (E_{ATD}−E_{BTD}) between a maximum expansion rate E_{ATD} (%) of the support in a TD direction during heating from T1 (° C.) to T2 (° C.) and an expansion rate E_{BTD} (%) of the support at T2 (° C.) at the end of heating is 4 or less and a lowest melt viscosity of the resin composition layer at T1 (° C.) or higher is 4,000 poises or more.

(6) The method for producing a printed wiring board according to any one of (1) to (5), wherein T1 satisfies a relation of 50° C.≦T1≦150° C.

(7) The method for producing a printed wiring board according to any one of (1) to (6), wherein T1 satisfies a relation of 120° C.≦T1≦150° C.

(8) The method for producing a printed wiring board according to any one of (1) to (7), wherein T2 satisfies a relation of 150° C.≦T2≦240° C.

(9) The method for producing a printed wiring board according to any one of (1) to (8), wherein thermal curing in the step (C) is performed by heating the adhesive sheet at T1 (° C.) and then at T2 (° C.).

(10) The method for producing a printed wiring board according to any one of (1) to (9), wherein the support is a plastic film.

(11) A semiconductor device, comprising a printed wiring board produced by the method according to any one of (1) to (10).

(12) A layered body comprising:
an internal layer substrate;
an insulating layer provided on the internal layer substrate; and
a support being in contact with the insulating layer, wherein
variation in a thickness of the insulating layer is 1 μm or less in a region except for 5% of a dimension of the support from edge portions of the support.

(13) An adhesive sheet, comprising a support and a resin composition layer provided on the support, wherein
during thermal curing by heating the adhesive sheet from T1 (° C.) to T2 (° C.), the adhesive sheet satisfies a relation of Y>2700X, wherein X is a sum ((E_{AMD}−E_{BMD})+(E_{ATD}−E_{BTD})) of a difference (E_{AMD}−E_{BMD}) between a maximum expansion rate E_{AMD} (%) of the support in an MD direction during heating from T1 (° C.) to T2 (° C.) and an expansion rate E_{BMD} (%) of the support at T2 (° C.) at the end of heating and a difference (E_{ATD}−E_{BTD}) between a maximum expansion rate E_{ATD} (%) of the support in a TD direction during heating from T1 (° C.) to T2 (° C.) and an expansion rate E_{BTD} (%) of the support at T2 (° C.) at the end of heating, and Y is a lowest melt viscosity (poise) of the resin composition layer at 120° C. or higher.

### Advantageous Effects of Invention

The present invention can provide a method for producing a printed wiring board that suppresses occurrence of curing unevenness and undulation even when a resin composition layer with a support attached thereto is thermally cured to form an insulating layer; an adhesive sheet and a layered body used in the method; and a semiconductor device provided with the printed wiring board produced by the method.

### BRIEF DESCRIPTION OF THE DRAWINGS

A more complete appreciation of the invention and many of the attendant advantages thereof will be readily obtained as the same become better understood by reference to the following detailed description when considered in connection with the accompanying drawings, wherein:

FIG. 1 is a schematic graph showing the expansion behavior of a support in TD and MD directions during heating;

FIG. 2 is a schematic graph showing the expansion behavior of a support in TD and MD directions during heating;

FIG. 3 is a schematic plan view of a layered body; and

FIG. 4 is a schematic view of a cut end surface of the layered body.

### EXPLANATION OF THE REFERENCE NUMERALS

10 layered body
10A dimension of support (length of support)
10B edge portion
10C central part
20 adhesive sheet
21 support
22 insulating layer
30 internal substrate

### DETAILED DESCRIPTION OF THE PREFERRED EMBODIMENTS

### Description of Terms

In the present invention, an “MD direction (machine direction)” of a support is a lengthwise direction of the support during production thereof, that is, a conveyance direction of the support during production. A “TD direction (transverse direction)” of the support is a width direction of the support during production thereof, and is orthogonal to the MD direction. Both the MD and TD directions are orthogonal to the thickness direction of the support.

In the present invention, an “expansion rate” of the support in the MD or TD direction of the support is an increase ratio (%) of a length (size) of the support in the MD or TD direction when the support is heated under a predetermined heating condition. The expansion rate (%) of the support is determined by an expression: (L−L₀)/L₀×100, wherein L₀ is the initial length of the support (i.e., the length of the support at the start of heating) and L is the length of the support after heating for a predetermined time. A positive expansion rate represents that the support expands under heating. A negative expansion rate represents that the support contracts under heating. The expansion rate (%) of the support can be determined by measuring a change in the length of the support in the MD or TD direction during heating under the predetermined heating condition using a thermomechanical analyzer. Examples of the thermomechanical analyzer may include “Thermo Plus TMA8310” manufactured by Rigaku Corporation and “TMA-SS6100” manufactured by Seiko Instruments Inc.

This heating condition is a condition that specifies characteristics such as the expansion rate of the support, and may or may not coincide with a condition in a “step (C) of thermally curing a resin composition layer to form an insulating layer” described below.

### Adhesive Sheet

Before a method for producing a printed wiring board of the present invention is described in detail, an “adhesive sheet” used in the method of the present invention will be described.

An adhesive sheet according to a first embodiment of the present invention is an adhesive sheet including a support and a resin composition layer provided on the support. When the adhesive sheet is thermally cured by heating from T1 (° C.) to T2 (° C.), the adhesive sheet satisfies a relation of Y >2700X, wherein X represents a sum ((E_{AMD}−E_{BMD})+(E_{ATD}−E_{BTD})) of a difference (E_{AMD}−E_{BMD}) between a maximum expansion rate E_{AMD} (%) of the support in the MD direction during heating from T1 (° C.) to T2 (° C.) and an expansion rate E_{BMD} (%) of the support at T2 (° C.) at the end of heating and a difference (E_{ATD}−E_{BTD}) between a maximum expansion rate E_{ATD} (%) of the support in the TD direction during heating from T1 (° C.) to T2 (° C.) and an expansion rate E_{BTD} (%) of the support at T2 (° C.) at the end of heating and Y (poise) represents the lowest melt viscosity of the resin composition layer at 120° C. or higher.

An adhesive sheet according to a second embodiment of the present invention is an adhesive sheet having a support and a resin composition layer provided on the support. When the adhesive sheet is thermally cured by heating from T1 (° C.) to T2 (° C.), a sum ((E_{AMD}−E_{BMD})+(E_{ATD}−E_{BTD})) of a difference (E_{AMD}−E_{BMD}) between a maximum expansion rate E_{AMD} (%) of the support in the MD direction during heating from T1 (° C.) to T2 (° C.) and an expansion rate E_{BMD} (%) of the support at T2 (° C.) at the end of heating and a difference (E_{ATD}−E_{BTD}) between a maximum expansion rate E_{ATD} (%) of the support in the TD direction during heating from T1 (° C.) to T2 (° C.) and an expansion rate E_{BTD} (%) of the support at T2 (° C.) at the end of heating is 4 or less and the lowest melt viscosity of the resin composition layer at T1 (° C.) or higher is 4,000 poises or more.

Herein, T1 (° C.) is lower than T2 (° C.).

The support generally expands or contracts when it is heated. A degree of expansion and contraction of the support varies depending on the types thereof. Due to a step of producing the support (for example, selection of materials constituting the support, and tension applied during winding the support conveyed (during conveyance)), the support tends to contract in the MD direction as compared with in the TD direction and tends to expand in the TD direction as compared with in the MD direction during heating.

In the present invention, the heating condition during thermal curing is adjusted to control the expansion and contraction of the support. In addition, the lowest melt viscosity of the resin composition layer is controlled in order to suppress the occurrence of curing unevenness and undulation caused by the expansion and contraction of the support.

Hereinafter, the support and the resin composition layer included in the adhesive sheets of the first and second embodiments will be described.

### Support

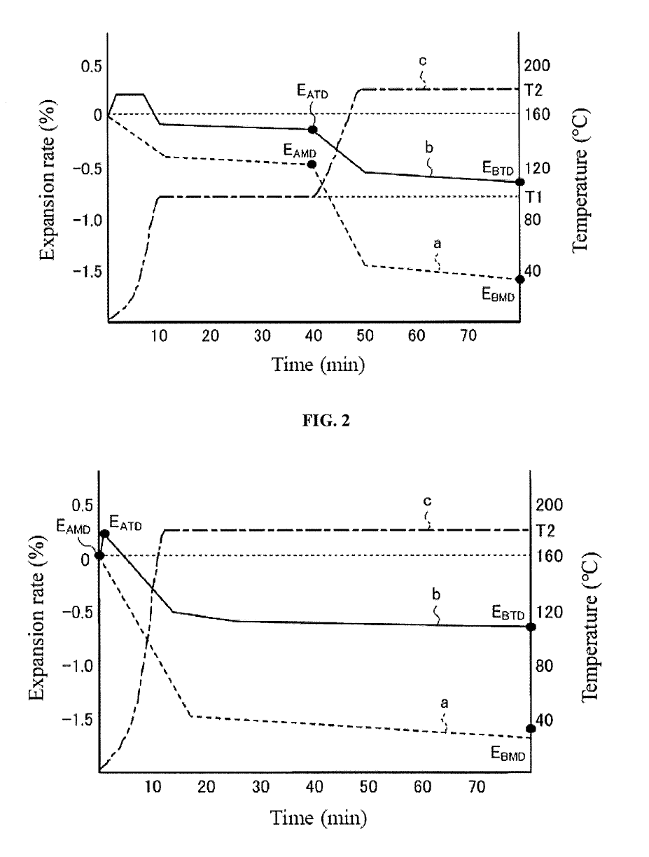

With reference to FIGS. 1 and 2, the outline of expansion behavior of the support according to the embodiments of the present invention will be described.

FIGS. 1 and 2 are schematic graphs showing the expansion behavior of the support in the TD and MD directions during formation of an insulating layer by thermal curing. In FIGS. 1 and 2, the left vertical axis represents the expansion rate (%) of the support in the TD and MD directions, the right vertical axis represents heating temperature (° C.), and the horizontal axis represents heating time (minutes). A line a represents the expansion behavior in the MD direction, a line b represents the expansion behavior in the TD direction, and a line c represents a temperature profile with time.

FIG. 1 is a graph showing the expansion behavior of the support when a temperature is increased from room temperature (e.g., 20° C.) to T1 (° C.), held at T1 (° C.) for 30 minutes, increased from T1 (° C.) to T2 (° C.), and held at T2 (° C.) under heating for 30 minutes. Specifically, thermal curing is performed by heating in two steps.

As is clear from FIG. 1 in the expansion behavior of the support in the MD direction, the expansion rate is decreased to a negative value at a process of increasing the temperature from room temperature to T1 (° C.) (for heating time of 0 minutes to 10 minutes). The expansion rate is gently decreased at a process of holding the temperature at T1 (° C.) for 30 minutes (for a heating time of 10 minutes to 40 minutes). The expansion rate is largely decreased at a process of increasing the temperature from T1 (° C.) to T2 (° C.) (for a heating time of 40 minutes to 50 minutes). The expansion rate is gently decreased at a process of holding the temperature at T2 (° C.) for 30 minutes (for a heating time of 50 minutes to 80 minutes).

The maximum expansion rate E_{AMD} (%) of the support in the MD direction during heating from T1 (° C.) to T2 (° C.) represents the maximum expansion rate E_{AMD} (%) of the support in the MD direction at the process of increasing the temperature from T1 (° C.) to T2 (° C.). In the context of FIG. 1, the maximum expansion rate E_{AMD} (%) is the expansion rate of the support in the MD direction at a time point of starting heating from T1 (° C.) to T2 (° C.) (at a time point of heating time of 40 minutes).

The expansion rate E_{BMD} (%) of the support in the MD direction at T2 (° C.) at the end of heating represents the expansion rate of the support in the MD direction at T2 (° C.) at which heating is completed. In the context of FIG. 1, the expansion rate E_{BMD} (%) is the expansion rate of the support in the MD direction at a time point of completing heating at T2 (° C.) (at a time point of heating time of 80 minutes).

As is clear from FIG. 1 in the expansion behavior of the support in the TD direction, the expansion rate is slightly increased temporarily at the process of increasing the temperature from room temperature to T1 (° C.) and becomes a negative value when the temperature reaches T1 (° C.) (for a heating time of 0 minutes to 10 minutes). The expansion rate is gently decreased at a process of heating at T1 (° C.) for 30 minutes (for a heating time of 10 minutes to 40 minutes). The expansion rate is largely decreased at the process of increasing the temperature from T1 (° C.) to T2 (° C.) (for a heating time of 40 minutes to 50 minutes). The expansion rate is gently decreased at the process of heating at T2 (° C.) for 30 minutes (for a heating time of 50 minutes to 80 minutes).

The maximum expansion rate E_{ATD} (%) of the support in the TD direction during heating from T1 (° C.) to T2 (° C.) represents the maximum expansion rate of the support in the TD direction at the process of increasing the temperature from T1 (° C.) to T2 (° C.). In the context of FIG. 1, the maximum expansion rate E_{ATD} (%) is the expansion rate of the support at a time point of starting heating from T1 (° C.) to T2 (° C.) (at a time point of heating time of 40 minutes).

The expansion rate E_{BTD} (%) of the support in the TD direction at the end of heating to T2 (° C.) represents the expansion rate of the support in the TD direction at T2 (° C.) at which heating is completed. In the context of FIG. 1, the expansion rate E_{BTD} (%) is the expansion rate of the support in the TD direction at a time point of completing heating at T2 (° C.) (at a time point of heating time of 80 minutes).

As is clear from the lines a and b in FIG. 1, the expansion rate E_{BTD} does not exceed the maximum expansion rate E_{ATD}, and also the expansion rate E_{BMD} does not exceed the maximum expansion rate E_{AMD}.

The temperature increasing rate at the process of increasing the temperature from T1 (° C.) to T2 (° C.) is preferably 1.5° C./min to 30° C./min, more preferably 2° C./min to 30° C./min, further preferably 4° C./min to 20° C./min, and still more preferably 4° C./min to 10° C./min. The temperature increasing rate at the process of increasing the temperature from room temperature to T1 (° C.) is the same.

FIG. 2 is a graph showing the expansion behavior of the support when the temperature is increased from room temperature (e.g., 20° C.) to T2 (° C.), and held at T2 (° C.) under heating for 65 minutes, that is, thermal curing is performed by heating in one step.

As is clear from FIG. 2 in the expansion behavior of the support in the MD direction, the expansion rate is largely decreased to a negative value at a process of increasing the temperature from room temperature to T2 (° C.) (for a heating time of 0 minutes to 15 minutes). The expansion rate is also decreased after the temperature reaches T2 (° C.) (for a heating time of 15 minutes to 20 minutes). At a process of holding the temperature at T2 (° C.) for 65 minutes (for a heating time of 15 minutes to 80 minutes), the expansion rate is gently decreased.

For heating in one step, T1 (° C.) may be room temperature. Therefore, when the adhesive sheet is thermally cured by heating in one step, the maximum expansion rate E_{AMD} (%) of the support in the MD direction during heating from T1 (° C.) to T2 (° C.) represents the maximum expansion rate of the support in the MD direction at the process of increasing the temperature from room temperature to T2 (° C.). In the context of FIG. 2, the maximum expansion rate E_{AMD} (%) is the expansion rate of the support in the MD direction at a time point of heating time of 0 minutes.

When the adhesive sheet is thermally cured by heating in one step, the expansion rate E_{BMD} (%) of the support in the MD direction at T2 (° C.) at the end of heating also represents the expansion rate of the support in the MD direction at a time point of completing heating at T2 (° C.). In the context of FIG. 2, the expansion rate E_{BMD} (%) is the expansion rate of the support in the MD direction at a time point of completing heating at T2 (° C.) (at a time point of heating time of 80 minutes).

As is clear from FIG. 2 in the expansion behavior of the support in the TD direction, the expansion rate is slightly increased temporarily at the process of increasing the temperature from room temperature to T2 (° C.) and largely decreased as the temperature approaches T2 (° C.) (for a heating time of 0 minutes to 15 minutes). The expansion rate is gently decreased at a process of holding the temperature at T2 (° C.) for 65 minutes (for a heating time of 15 minutes to 80 minutes).

When the adhesive sheet is thermally cured by heating in one step, the maximum expansion rate E_{ATD} (%) of the support in the TD direction during heating from T1 (° C.) to T2 (° C.) represents the maximum expansion rate of the support in the TD direction at the process of increasing the temperature from room temperature to T2 (° C.). In the context of FIG. 2, the maximum expansion rate E_{ATD} (%) is the expansion rate of the support in the TD direction at a time point of heating time of 3 minutes.

When the adhesive sheet is thermally cured by heating in one step, the expansion rate E_{BTD} (%) of the support in the TD direction at T2 (° C.) at the end of heating also represents the expansion rate of the support in the TD direction at a time point of completing heating at T2 (° C.). In the context of FIG. 2, the expansion rate E_{BTD} (%) is the expansion rate of the support in the TD direction at a time point of completing heating at T2 (° C.) (at a time point of heating time of 80 minutes).

As is clear from the lines a and b in FIG. 2, the expansion rate E_{BTD} does not exceed the maximum expansion rate E_{ATD}, and also the expansion rate E_{BMD} does not exceed the maximum expansion rate E_{AMD}.

The temperature increasing rate at the process of increasing the temperature from room temperature to T2 (° C.) is preferably 1.5° C./min to 30° C./min, more preferably 2° C./min to 30° C./min, further preferably 4° C./min to 20° C./min, and still more preferably 4° C./min to 10° C./min.

In the first and second embodiments, a difference (E_{AMD}−E_{BMD}) between the maximum expansion rate E_{AMD} (%) and the expansion rate E_{BMD} (%) may be 0.05 or more, 0.1 or more, or 0.3 or more. The upper limit of the difference is preferably 3 or less, more preferably 2.5 or less, and further preferably 2 or less.

In the first and second embodiments, a difference (E_{ATD}−E_{BTD}) between the maximum expansion rate E_{ATD} (%) and the expansion rate E_{BTD} (%) may be 0.05 or more, 0.1 or more, or 0.2 or more. The upper limit of the difference is preferably 3 or less, more preferably 2.5 or less, and further preferably 2 or less.

In the adhesive sheet of the first embodiment, X ((E_{AMD}−E_{BMD})+(E_{ATD}−E_{BTD})) is not particularly limited, and is preferably 4 or less, more preferably 3.9 or less, and further preferably 3.8 or less or 3.7 or less. The lower limit thereof may be 0.01 or more, 0.5 or more, or 0.8 or more. 2700X is preferably 10,800 or less, more preferably 10,530 or less, and further more preferably 10,260 or less or 9,990 or less. The lower limit thereof is preferably 27 or more, more preferably 1,350 or more, and further preferably 2,160 or more.

2700X in the relational expression (Y>2700X) of the adhesive sheet of the first embodiment preferably exceeds 300 in order to effectively suppress the undulation. Therefore, it is preferable that the adhesive sheet satisfy a relation of Y>2700X>300.

In the adhesive sheet of the second embodiment, (E_{AMD}−E_{BMD})+(E_{ATD}−E_{BTD}) is 4 or less, preferably 3.9 or less, more preferably 3.8 or less, and further preferably 3.7 or less. The lower limit thereof may be 0.01 or more, 0.5 or more, or 0.8 or more.

In the present invention, the expansion rate of the support at a temperature of lower than T1 (° C.) is not particularly limited. The support may have an expansion rate of more than 0% as long as the object of the present invention is not impaired. This is because, even if curing unevenness and undulation are caused by expansion of the support at a temperature of lower than T1 (° C.), the curing unevenness and undulation can be self-alignedly converted into a flattened surface by melting the resin composition layer as described below when the expansion rate of the support becomes 0% or less. In order to obtain a flattening effect through this self alignment, the expansion rate at a temperature of lower than T1 (° C.) is preferably 2% or less.

A temperature at which the support begins to rapidly expand is generally about 120° C. A temperature at which the expansion rate of the support in the MD direction is the largest is not particularly limited, and is 60° C. or higher or 80° C. or higher. A temperature at which the expansion rate of the support in the TD direction is the largest is not particularly limited, and is 60° C. or higher or 80° C. or higher.

In the context of FIG. 1, that is, heating in two steps, T1 (° C.) is not particularly limited as long as it is lower than T2 (° C.). In order to decrease generation of voids due to foaming of a solvent component, T1 preferably satisfies a relation of 50° C.≦T1≦150° C., more preferably 80° C.≦T1≦150° C., and further preferably 120° C.≦T1≦150° C.

In the context of FIG. 2, that is, heating in one step, T1 (° C.) is not particularly limited as long as it is lower than T2 (° C.). T1 preferably satisfies a relation of 0° C.≦T1≦50° C., more preferably 5° C.≦T1≦40° C., and further preferably 10° C.≦T1≦30° C.

T2 (° C.) is not particularly limited as long as it is higher than T1 (° C.) and allows the resin composition layer to be thermally cured. T2 preferably satisfies a relation of 150° C.≦T2≦240° C., more preferably 155° C.≦T2≦200° C., and further preferably 170° C.≦T2≦180° C.

For the support, a film of a plastic material (hereinafter may be simply referred to as a “plastic film”) is suitably used since it is lightweight and has strength required to produce a printed wiring board. Examples of the plastic material may include polyester such as polyethylene terephthalate (referred to as “PET”) and polyethylene naphthalate (referred to as “PEN”), polycarbonate (referred to as “PC”), acryl such as polymethyl methacrylate (PMMA), cyclic polyolefin, triacetylcellulose (TAC), polyether sulfide (PES), polyether ketone, and polyimide. Among them, polyethylene terephthalate and polyethylene naphthalate are preferable, and polyethylene terephthalate is particularly preferable since it is inexpensive.

In one preferred embodiment of the present invention, a support of the plastic film or the like is subjected to a pre-heating treatment to control expansion and contraction thereof. The pre-heating treatment can be performed by changing conditions according to the type of the plastic material, the presence or absence of tension (stretching) applied during production, the axial direction of stretching, the degree of stretching, a heating treatment condition after stretching, or the like so that the sum X of differences (E_{AMD}−E_{BMD}) and (E_{ATD}−E_{BTD}) satisfies a desired range.

When the plastic film is an elongated plastic film, the pre-heating treatment of controlling the expansion and contraction of the support may be, for example, a heating treatment with application of tension in one or both of the MD and TD directions of the plastic film.

When the elongated plastic film is used, a predetermined tension has been usually applied in the MD direction by conveyance using rollers such as conveying rollers during production. Therefore, the differences (E_{AMD}−E_{BMD}) and (E_{ATD}−E_{BTD}) of the support may satisfy desired values by heating it while a tension is applied only in the TD direction.

When a tension applied to the plastic film stretched between a plurality of rollers is adjusted, the predetermined tension can be applied in the MD direction. A tension can be applied in the TD direction by any suitable means that is conventionally known. Specifically, the predetermined tension can be applied in the TD direction by a tenter having a conventionally known configuration or the like.

For example, the predetermined tension can be applied in the MD or TD direction of the plastic film using the weight and gravity of a weight member. Specifically, an end edge in a direction to be adjusted of the plastic film is fixed in a support stub using any suitable adhesive member (e.g., Kapton adhesive tape, PTFE adhesive tape, and glass cloth adhesive tape) so that a direction to be adjusted among the TD and MD directions coincides with the vertical direction, and hung so that a tension is evenly applied to the whole plastic film. After that, another end edge in an opposite direction to the direction to be adjusted is connected to the weight member such as a metal plate using any suitable adhesive member so that a tension is evenly applied to the whole plastic film. The plastic film may be then subjected to the pre-heating treatment by heating while a tension is applied by the weight of the weight member.

The tension applied to the plastic film can be set to any suitable tension in consideration of the material for the plastic film, the expansion rate, a composition of the resin composition, and the like. For example, the tension may be 1 gf/cm² to 40 gf/cm².

In one embodiment, the heating temperature of the pre-heating treatment is preferably (Tg+50°) C. or higher, more preferably (Tg+60°) C. or higher, further preferably (Tg+70°) C. or higher, and still more preferably (Tg+80°) C. or higher or (Tg+90°) C. or higher. Herein, Tg is the glass transition temperature of the plastic film. The upper limit of the heating temperature is not particularly limited as long as it is lower than the melting point of the plastic film, and is preferably (Tg+115°) C. or lower, more preferably (Tg+110°) C. or lower, and further preferably (Tg+105°) C. or lower.

For example, when the support is a PET film, the heating temperature of the pre-heating treatment is preferably 100° C. or higher, more preferably 110° C. or higher, further preferably 120° C. or higher, and still more preferably 125° C. or higher or 130° C. or higher. The upper limit of the heating temperature is preferably 195° C. or lower, more preferably 190° C. or lower, and further preferably 185° C. or lower, 180° C. or lower, or 175° C. or lower.

The heating time may be appropriately determined according to the heating temperature in order to control the expansion and contraction of the support. In one embodiment, the heating time is preferably 1 minute or longer, more preferably 2 minutes or longer, and further preferably 5 minutes or longer, 10 minutes or longer, or 15 minutes or longer. The upper limit of the heating time varies depending on the heating temperature, and is preferably 120 minutes or shorter, more preferably 90 minutes or shorter, and further preferably 60 minutes or shorter.

An atmosphere during the pre-heating treatment is not particularly limited. Examples thereof may include an air atmosphere and an inert gas atmosphere such as a nitrogen gas atmosphere, a helium gas atmosphere, and an argon gas atmosphere. An air atmosphere is preferable since the support can be easily prepared.

The pre-heating treatment may be performed under any of reduced pressure, normal pressure, and increased pressure. A normal pressure is preferable since the support can be easily prepared.

A surface of the support which is to be in contact with the resin composition layer described below may be subjected to a mat treatment or a corona treatment.

As the support, a support with a release layer which has a release layer on a surface to be in contact with the resin composition layer may be used. Examples of a release agent used for the release layer of the support with a release layer may include one or more release agents selected from the group consisting of an alkyd resin, a polyolefin resin, a urethane resin, and a silicone resin. As the support with a release layer, a commercially available product may be used. Examples thereof may include “SK-1,” “AL-5,” and “AL-7” available from Lintec Corporation and “Lumirror T6AM” available from Toray Industries, Inc., which are PET films with a release layer containing an alkyd resin-based release agent as a main component.

The thickness of the support is not particularly limited, and is preferably in a range of 5 μm to 75 μM, more preferably in a range of 10 μm to 60 μm, and further preferably in a range of 10 μm to 45 μm. When the support with a release layer is used, the total thickness of the support with a release layer preferably falls within the above-described range.

### Resin Composition Layer

A resin composition used for the resin composition layer included in the adhesive sheet is not particularly limited as long as a cured product thereof may have sufficient hardness and insulation properties. Examples of the resin composition may include a composition containing a curable resin and a curing agent for the curable resin. As the curable resin, any conventionally known curable resin used for forming an insulating layer of a printed wiring board can be used. In particular, an epoxy resin is preferably used. In one embodiment, the resin composition contains (a) an epoxy resin, (b) a curing agent, and (c) an inorganic filler. The resin composition may further contain a thermoplastic resin, a curing accelerator, a flame retardant, and an organic filler, if necessary.

Each component that may be used as a material for the resin composition will be described in detail below.

### (a) Epoxy Resin

Examples of the epoxy resin may include a bixylenol type epoxy resin, a bisphenol A type epoxy resin, a bisphenol F type epoxy resin, a bisphenol S type epoxy resin, a bisphenol AF type epoxy resin, a dicyclopentadiene type epoxy resin, a trisphenol type epoxy resin, a naphthol novolac type epoxy resin, a phenol novolac type epoxy resin, a tert-butyl-catechol type epoxy resin, a naphthalene type epoxy resin, a naphthol type epoxy resin, an anthracene type epoxy resin, a glycidyl amine type epoxy resin, a glycidyl ester type epoxy resin, a cresol novolac type epoxy resin, a biphenyl type epoxy resin, a linear aliphatic epoxy resin, an epoxy resin having a butadiene structure, an alicyclic epoxy resin, a heterocyclic epoxy resin, a spiro ring-containing epoxy resin, a cyclohexane dimethanol type epoxy resin, a naphthylene ether type epoxy resin, a trimethylol type epoxy resin, and a tetraphenyl ethane type epoxy resin. The epoxy resin may be used alone or in combination of two or more kinds thereof. In order to decrease the average coefficient of linear thermal expansion, an epoxy resin containing an aromatic skeleton is preferable as the component (a). One or more selected from a bisphenol A type epoxy resin, a bisphenol F type epoxy resin, a naphthalene type epoxy resin, a biphenyl type epoxy resin, and a dicyclopentadiene type epoxy resin are more preferable. A bisphenol A type epoxy resin and a naphthalene type epoxy resin are further preferable. The aromatic skeleton is generally a chemical structure defined as aromatic, and contains a polycyclic aromatic ring and a heteroaromatic ring.

It is preferable that the epoxy resin contain an epoxy resin having two or more epoxy groups per molecule. It is preferable that an epoxy resin having two or more epoxy groups per molecule in an amount of at least 50% by mass or more relative to 100% by mass of nonvolatile components in the epoxy resin be contained. In particular, it is preferable that the epoxy resin contain an epoxy resin that has two or more epoxy groups per molecule and is liquid at 20° C. (hereinafter referred to as “liquid epoxy resin”) and an epoxy resin that has three or more epoxy groups per molecule and is solid at 20° C. (hereinafter referred to as “solid epoxy resin”). When the liquid epoxy resin and the solid epoxy resin are used in combination as the epoxy resin, a resin composition having excellent flexibility can be obtained. Further, the rupture strength of cured product of the resin composition is enhanced.

The liquid epoxy resin is preferably a bisphenol A type epoxy resin, a bisphenol F type epoxy resin, a bisphenol AF type epoxy resin, a naphthalene type epoxy resin, a glycidyl ester type epoxy resin, a glycidyl amine type epoxy resin, a phenol novolac type epoxy resin, an alicyclic epoxy resin having an ester skeleton, a cyclohexane dimethanol type epoxy resin, a glycidyl amine type epoxy resin, or an epoxy resin having a butadiene structure; and more preferably a glycidyl amine type epoxy resin, a bisphenol A type epoxy resin, a bisphenol F type epoxy resin, a bisphenol AF type epoxy resin, or a naphthalene type epoxy resin. Specific examples of the liquid epoxy resin may include “HP4032,” “HP4032D,” and “HP4032SS” (naphthalene type epoxy resins) available from DIC Corporation; “828US,” “jER828EL,” and “Epicoat 828EL” (bisphenol A type epoxy resin), “jER807” and “1750” (bisphenol F type epoxy resin), “jER152” (phenol novolac type epoxy resin), and “630” and “630LSD” (glycidyl amine type epoxy resin) available from Mitsubishi Chemical Corporation; “ZX1059” (mixed product of bisphenol A type epoxy resin and bisphenol F type epoxy resin) available from Nippon Steel & Sumikin Chemical Co., Ltd.; “EX-721” (glycidyl ester type epoxy resin) available from Nagase ChemteX Corporation; “CELLOXIDE 2021P” (alicyclic epoxy resin having an ester skeleton) and “PB-3600” (epoxy resin having a butadiene structure) available from Daicel Corporation; “ZX1658” and “ZX1658GS” (liquid 1,4-glycidylcyclohexane) available from Nippon Steel Chemical Co., Ltd; “630LSD” (glycidyl amine type epoxy resin) available from Mitsubishi Chemical Corporation. These may be used alone or in combination of two or more kinds thereof.

The solid epoxy resin is preferably a tetrafunctional naphthalene type epoxy resin, a cresol novolac type epoxy resin, a dicyclopentadiene type epoxy resin, a trisphenol type epoxy resin, a naphthol type epoxy resin, a biphenyl type epoxy resin, a naphthylene ether type epoxy resin, an anthracene type epoxy resin, a bisphenol A type epoxy resin, or a tetraphenylethane type epoxy resin; and more preferably a tetrafunctional naphthalene type epoxy resin, a naphthalene type epoxy resin, a naphthol type epoxy resin, or a biphenyl type epoxy resin. Specific examples of the solid epoxy resin may include “HP4032H” (naphthalene type epoxy resin), “HP-4700” and “HP-4710” (tetrafunctional naphthalene type epoxy resin), “N-690” (cresol novolac type epoxy resin), “N-695” (cresol novolac type epoxy resin), “HP-7200” (dicyclopentadiene type epoxy resin), “HP-7200HH,” “HP-7200H,” “EXA-7311,” “EXA-7311-G3,” “EXA-7311-G4,” “EXA-7311-G4S,” and “HP6000” (naphthylene ether type epoxy resin) available from DIC Corporation; “EPPN-502H” (trisphenol epoxy resin), “NC7000L” (naphthol novolac epoxy resin), “NC3000H,” “NC3000,” “NC3000L,” and “NC3100” (biphenyl type epoxy resin) available from Nippon Kayaku Co., Ltd.; “ESN475V” (naphthalene type epoxy resin) and “ESN485” (naphthol novolac epoxy resin) available from Nippon Steel & Sumikin Chemical Co., Ltd.; “YX4000H,” “YX4000,” and “YL6121” (biphenyl type epoxy resin), “YX4000HK” (bixylenol type epoxy resin), and “YX8800” (anthracene type epoxy resin) available from Mitsubishi Chemical Corporation; “PG-100” and “CG-500” available from Osaka Gas Chemicals Co., Ltd.; “YL7760” (bisphenol AF type epoxy resin) and “YL7800” (fluorene type epoxy resin) available from Mitsubishi Chemical Corporation; and “jER1010” (solid bisphenol A type epoxy resin) and “jER10315” (tetraphenylethane type epoxy resin) available from Mitsubishi Chemical Corporation. These may be used alone or in combination of two or more kinds thereof.

When the liquid epoxy resin and the solid epoxy resin are used in combination as the epoxy resin, a mass ratio thereof (liquid epoxy resin:solid epoxy resin) is preferably in a range of 1:0.1 to 1:15. When the mass ratio of the liquid epoxy resin to the solid epoxy resin falls within such a range, the following effects can be obtained: i) moderate tackiness can be obtained when the resin composition is used in an adhesive sheet form; ii) sufficient flexibility can be obtained when the resin composition is used in an adhesive sheet form, and as a result, handleability is improved; and iii) a cured product having sufficient rupture strength can be obtained. From the viewpoints of the effects i) to iii), the mass ratio of the liquid epoxy resin to the solid epoxy resin (liquid epoxy resin:solid epoxy resin) is more preferably in a range of 1:0.5 to 1:10, and further preferably in a range of 1:1.1 to 1:8.

The content of the epoxy resin in the resin composition is preferably 1% by mass or more, more preferably 2% by mass or more, and further preferably 3% by mass or more in order to obtain an insulating layer having good mechanical strength and insulation reliability. The upper limit of the content of the epoxy resin is not particularly limited as long as the effects of the present invention are exerted, and is preferably 60% by mass or less, more preferably 50% by mass or less, and further preferably 40% by mass or less.

In the present invention, the content of each component in the resin composition is a value relative to 100% by mass of nonvolatile component in the resin composition unless otherwise specified.

The epoxy equivalent weight of the epoxy resin is preferably 50 to 5,000, more preferably 50 to 3,000, further preferably 80 to 2,000, and still more preferably 110 to 1,000. When the epoxy equivalent weight falls within such a range, the crosslink density of a cured product becomes sufficient, and an insulating layer having small surface roughness can be provided. The epoxy equivalent weight can be measured in accordance with JIS K7236. The epoxy equivalent weight is the mass of the resin containing one equivalent of epoxy group.

The weight average molecular weight of the epoxy resin is preferably 100 to 5,000, more preferably 250 to 3,000, and further preferably 400 to 1,500. Herein, the weight average molecular weight of the epoxy resin is a polystyrene-equivalent weight average molecular weight measured by a gel permeation chromatography (GPC) method.

### (b) Curing Agent

The curing agent is not particularly limited as long as it has a function of curing the epoxy resin. Examples thereof may include a phenol-based curing agent, a naphthol-based curing agent, an active ester-based curing agent, a benzoxazine-based curing agent, a cyanate ester-based curing agent, and a carbodiimide-based curing agent. The curing agent may be used alone or in combination of two or more kinds thereof. It is preferable that the component (b) is one or more selected from a phenol-based curing agent, a naphthol-based curing agent, an active ester curing agent, a carbodiimide-based curing agent, and a cyanate ester-based curing agent.

From the viewpoints of heat resistance and water resistance, it is preferable that the phenol-based curing agent and the naphthol-based curing agent be a phenol-based curing agent having a novolac structure and a naphthol-based curing agent having a novolac structure, respectively. From the viewpoint of adhesion to a conductive layer, a nitrogen-containing phenol-based curing agent is preferable, and a triazine skeleton-containing phenol-based curing agent is more preferable. Among them, a triazine skeleton-containing phenol novolac curing agent is preferable in order to highly satisfy heat resistance, water resistance, and adhesion to a conductive layer.

Specific examples of the phenol-based curing agent and the naphthol-based curing agent may include “MEH-7700,” “MEH-7810,” “MEH-7851,” and “MEH-7851H” available from Meiwa Plastic Industries, Ltd.; “NHN,” “CBN,” and “GPH” available from Nippon Kayaku Co., Ltd.; “SN170,” “SN180,” “SN190,” “SN475,” “SN485,” “SN495,” “SN375,” and “SN395” available from Nippon Steel & Sumikin Chemical Co., Ltd.; and “TD-2090,” “LA-7052,” “LA-7054,” “LA-1356,” “LA-3018-50P,” “LA-3018,” and “EXB-9500” available from DIC Corporation.

In order to obtain an insulating layer having excellent adhesion to a conductive layer, an active ester-based curing agent is also preferable. The active ester-based curing agent is not particularly limited, and a compound having two or more highly reactive ester groups per molecule, such as phenol esters, thiophenol esters, N-hydroxyamine esters, and esters of heterocyclic hydroxy compounds, is generally preferably used. It is preferable that the active ester-based curing agent be an active ester-based curing agent obtained by a condensation reaction of a carboxylic acid compound and/or a thiocarboxylic acid compound with a hydroxy compound and/or a thiol compound. In order to especially enhance the heat resistance, an active ester-based curing agent obtained from a carboxylic acid compound and a hydroxy compound is preferable, and an active ester-based curing agent obtained from a carboxylic acid compound and a phenol compound and/or a naphthol compound is more preferable. Examples of the carboxylic acid compound may include benzoic acid, acetic acid, succinic acid, maleic acid, itaconic acid, phthalic acid, isophthalic acid, terephthalic acid, and pyromellitic acid. Examples of the phenol compound or naphthol compound may include hydroquinone, resorcin, bisphenol A, bisphenol F, bisphenol S, phenolphthalin, methylated bisphenol A, methylated bisphenol F, methylated bisphenol S, phenol, o-cresol, m-cresol, p-cresol, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucin, benzenetriol, a dicyclopentadiene type diphenol compound, and phenol novolac. The “dicyclopentadiene type diphenol compound” herein is a diphenol compound obtained by condensation of one dicyclopentadiene molecule with two phenol molecules.

Specifically, an active ester compound containing a dicyclopentadiene type diphenol structure, an active ester compound containing a naphthalene structure, an active ester compound containing an acetylated compound of phenol novolac, and an active ester compound containing a benzoylated compound of phenol novolac are preferable. Among them, an active ester compound containing a naphthalene structure and an active ester compound containing a dicyclopentadiene type diphenol structure are more preferable. The “dicyclopentadiene type diphenol structure” is a divalent structural unit of phenylene-dicyclopentylene-phenylene.

Examples of a commercially available product of the active ester-based curing agent may include “EXB9451,” “EXB9460,” “EXB9460S,” “HPC-8000-65T,” “HPC-8000H-65TM,” and “EXB-8000L-65TM” as an active ester compound containing a dicyclopentadiene type diphenol structure (available from DIC Corporation), “EXB9416-70BK” as an active ester compound containing a naphthalene structure (available from DIC Corporation), “DC808” as an active ester compound containing an acetylated compound of phenol novolac (available from Mitsubishi Chemical Corporation), “YLH1026” as an active ester compound containing a benzoylated compound of phenol novolac (available from Mitsubishi Chemical Corporation), “DC808” as an active ester curing agent that is an acetylated compound of phenol novolac (available from Mitsubishi Chemical Corporation), and “YLH1026,” “YLH1030,” and “YLH1048” as an active ester curing agent that is a benzoylated compound of phenol novolac (available from Mitsubishi Chemical Corporation).

Specific examples of the benzoxazine-based curing agent may include “HFB2006M” available from Showa Highpolymer Co., Ltd., and “P-d” and “F-a” available from Shikoku Chemicals Corporation.

Examples of the cyanate ester-based curing agent may include a bifunctional cyanate resin such as bisphenol A dicyanate, polyphenol cyanate, oligo(3-methylene-1,5-phenylenecyanate), 4,4′-methylenebis(2,6-dimethylphenyl cyanate), 4,4′-ethylidenediphenyl dicyanate, hexafluorobisphenol A dicyanate, 2,2-bis(4-cyanate)phenylpropane, 1,1-bis(4-cyanatephenylmethane), bis(4-cyanate-3,5-dimethylphenyl)methane, 1,3-bis(4-cyanatephenyl-1-(methylethylidene))benzene, bis(4-cyanatephenyl)thioether, and bis(4-cyanatephenyl)ether; a polyfunctional cyanate resin derived from phenol novolac and cresol novolac; and a prepolymer in which these cyanate resin are partly triazinized. Specific examples of the cyanate ester-based curing agent may include “PT30” and “PT60” (both phenol novolac type polyfunctional cyanate ester resins) and “BA230” and “BA230S75” (prepolymer in which bisphenol A dicyanate is partly or entirely triazinized to form a trimer) available from Lonza Japan Ltd. Specific examples of the carbodiimide-based curing agent may include “V-03” and “V-07” available from Nisshinbo Chemical Inc.

The quantitative ratio of the epoxy resin to the curing agent, in terms of a ratio of (the total number of epoxy groups in the epoxy resin): (the total number of reactive groups in the curing agent), is preferably in a range of 1:0.01 to 1:2, more preferably in a range of 1:0.05 to 1:1.5, and further preferably in a range of 1:0.1 to 1:1. Herein, the reactive group in the curing agent is an active hydroxyl group, an active ester group, or the like, and varies depending on the kind of the curing agent. The total number of epoxy groups in the epoxy resin is a value obtained by dividing the mass of solid content in each epoxy resin by respective epoxy equivalent weights and summing the calculated values for all the epoxy resins. The total number of reactive groups in the curing agent is a value obtained by dividing the mass of solid content in each curing agent by respective reactive group equivalent weights and summing the calculated values for all the curing agents. When the quantitative ratio of the epoxy resin to the curing agent falls within such a range, the heat resistance of the cured product of the resin composition is more improved.

In one embodiment, the resin composition contains (a) the epoxy resin and (b) the curing agent noted above. It is preferable that the resin composition contain a mixture of the liquid epoxy resin and the solid epoxy resin as (a) the epoxy resin (the mass ratio of the liquid epoxy resin to the solid epoxy resin is preferably 1:0.1 to 1:15, more preferably 1:0.5 to 1:10, and further preferably 1:1.1 to 1:8), and one or more selected from the group consisting of the phenol-based curing agent, the naphthol-based curing agent, the active ester curing agent, the carbodiimide-based curing agent, and the cyanate ester-based curing agent as (b) the curing agent.

The content of the curing agent in the resin composition is not particularly limited, and is preferably 45% by mass or less, more preferably 40% by mass or less, and further preferably 35% by mass or less. The lower limit thereof is not particularly limited, and is preferably 3% by mass or more, and more preferably 5% by mass or more.

### (c) Inorganic Filler

A material for the inorganic filler is not particularly limited. Examples thereof may include silica, alumina, glass, cordierite, silicon oxide, barium sulfate, barium carbonate, talc, clay, a mica powder, zinc oxide, hydrotalcite, boehmite, aluminum hydroxide, magnesium hydroxide, calcium carbonate, magnesium carbonate, magnesium oxide, boron nitride, aluminum nitride, manganese nitride, aluminum borate, strontium carbonate, strontium titanate, calcium titanate, magnesium titanate, bismuth titanate, titanium oxide, zirconium oxide, barium titanate, barium zirconate titanate, barium zirconate, calcium zirconate, zirconium phosphate, zirconium tungstate phosphate, and silicon carbide. Among them, silicon carbide and silica are preferable, and silica is particularly preferable. It is preferable that silica have a spherical shape. The inorganic filler may be used alone or in combination of two or more kinds thereof.

The average particle diameter of the inorganic filler is not particularly limited. In order to obtain an insulating layer having improved circuit embeddability and low surface roughness, the average particle diameter is preferably 5 μm or less, more preferably 2.5 μm or less, further preferably 2.2 μm or less, and still more preferably 2 μm or less. The lower limit thereof is not particularly limited, and is preferably 0.01 μm or more, more preferably 0.05 μm or more, and further preferably 0.1 μm or more. Examples of commercially available product of the inorganic filler having such an average particle diameter may include “YC100C,” “YA050C,” “YA050C-MJE,” and “YA010C” available from Admatechs Company Limited; “UFP-30” available from Denki Kagaku Kogyo Kabushiki Kaisha; “Silfil NSS-3N,” “Silfil NSS-4N,” and “Silfil NSS-5N” available from Tokuyama Corporation; and “SC2500SQ,” “SO-C6,” “SO-C4,” “SO-C2,” and “SO-C1” available from Admatechs Company Limited.

The average particle diameter of the inorganic filler can be measured by a laser diffraction and scattering method on the basis of the Mie scattering theory. Specifically, the particle size distribution of the inorganic filler is prepared on the basis of volume, and a median diameter thereof can be measured as an average particle diameter using a laser diffraction and scattering particle size distribution measuring device. As a measurement sample, a dispersion in which the inorganic filler is dispersed in methyl ethyl ketone by ultrasonication can be preferably used. As the laser diffraction and scattering particle size distribution measuring device, “SALD-2200” manufactured by Shimadzu Corporation or the like can be used.

In order to enhance the humidity resistance and dispersibility, it is preferable that the inorganic filler be treated with one or more kinds of surface treatment agents such as an aminosilane-based coupling agent, an epoxysilane-based coupling agent, a mercaptosilane-based coupling agent, an alkoxysilane compound, an organosilazane compound, and a titanate-based coupling agent. Examples of a commercially available surface treatment agent may include “KBM403” (3-glycidoxypropyltrimethoxysilane), “KBM803” (3-mercaptopropyltrimethoxysilane), “KBE903” (3-aminopropyltriethoxysilane), “KBM573” (N-phenyl-3-aminopropyltrimethoxysilane), “SZ-31” (hexamethyldisilazane), “KBM-103” (phenyltrimethoxysilane), and “KBM-4803” (long-chain epoxy type silane coupling agent), all available from Shin-Etsu Chemical Co., Ltd. The surface treatment agent may be used alone or in combination of two or more kinds thereof.

The degree of surface treatment with the surface treatment agent can be evaluated by the amount of carbon per unit surface area of the inorganic filler. In order to enhance the dispersibility of the inorganic filler, the amount of carbon per unit surface area of the inorganic filler is preferably 0.02 mg/m² or more, more preferably 0.1 mg/m² or more, and further preferably 0.2 mg/m² or more. In order to suppress an increase in the melt viscosity of resin varnish and the melt viscosity in a sheet form, the amount of carbon per unit surface area of the inorganic filler is preferably 1 mg/m² or less, more preferably 0.8 mg/m² or less, and further preferably 0.5 mg/m² or less.

The amount of carbon per unit surface area of the inorganic filler can be measured after the surface-treated inorganic filler is washed with a solvent such as methyl ethyl ketone (MEK). Specifically, a sufficient amount of MEK is added as the solvent to the inorganic filler which is surface-treated with the surface treatment agent, and the resultant mixture is washed by ultrasonication at 25° C. for 5 minutes. A supernatant liquid is removed and a solid content is dried. The amount of carbon per unit surface area of the inorganic filler can be measured using a carbon analyzer. As the carbon analyzer, “EMIA-320V” manufactured by Horiba Ltd., or the like can be used.

In order to obtain an insulating layer having low thermal expansion coefficient, the content of the inorganic filler in the resin composition is preferably 30% by mass or more, more preferably 35% by mass or more, and further preferably 36% by mass or more. From the viewpoints of mechanical strength of the insulating layer, and in particular, elongation thereof, the upper limit thereof is preferably 80% by mass or less, more preferably 75% by mass or less, and further preferably 70% by mass or less.

### (d) Thermoplastic Resin

Examples of the thermoplastic resin may include a phenoxy resin, a polyvinyl acetal resin, a polyolefine resin, a polybutadiene resin, a polyimide resin, a polyamideimide resin, a polyetherimide resin, a polysulfone resin, a polyether sulfone resin, a polyphenylene ether resin, a polycarbonate resin, a polyetherether ketone resin, and a polyester resin. A phenoxy resin is preferable. The thermoplastic resin may be used alone or in combination of two or more kinds thereof.

The polystyrene-equivalent weight average molecular weight of the thermoplastic resin is preferably in a range of 8,000 to 70,000, more preferably in a range of 10,000 to 60,000, and further preferably in a range of 20,000 to 60,000. The polystyrene-equivalent weight average molecular weight of the thermoplastic resin is measured by the gel permeation chromatography (GPC) method. Specifically, the polystyrene-equivalent weight average molecular weight of the thermoplastic resin can be determined by measurement using LC-9A/RID-6A manufactured by Shimadzu Corporation as a measurement apparatus, Shodex K-800P/K-804L/K-804L manufactured by Showa Denko K.K., as columns, and chloroform or the like as a mobile phase. The measurement is performed at a column temperature of 40° C., and the polystyrene-equivalent weight average molecular weight can be computed using a standard polystyrene calibration curve.

Examples of the phenoxy resin may include phenoxy resins having one or more skeletons selected from the group consisting of a bisphenol A skeleton, a bisphenol F skeleton, a bisphenol S skeleton, a bisphenol acetophenone skeleton, a novolac skeleton, a biphenyl skeleton, a fluorene skeleton, a dicyclopentadiene skeleton, a norbornene skeleton, a naphthalene skeleton, an anthracene skeleton, an adamantane skeleton, a terpene skeleton, and a trimethyl cyclohexane skeleton. A terminal ends of the phenoxy resin may be any functional group such as a phenolic hydroxyl group and an epoxy group. The phenoxy resin may be used alone or in combination of two or more kinds thereof. Specific examples of the phenoxy resin may include “1256” and “4250” (both bisphenol A skeleton-containing phenoxy resins), “YX8100” (bisphenol S skeleton-containing phenoxy resin), and “YX6954” (bisphenol acetophenone skeleton-containing phenoxy resin) available from Mitsubishi Chemical Corporation. Additional examples thereof may include “FX280” and “FX293” available from Nippon Steel & Sumikin Chemical Co., Ltd., and “YX6954BH30,” “YX7553,” “YX7553BH30,” “YL7553BH30,” “YL7769BH30,” “YL6794,” “YL7213,” “YL7290,” “YL7891BH30,” and “YL7482” available from Mitsubishi Chemical Corporation.

Examples of the polyvinyl acetal resin may include a polyvinyl formal resin and a polyvinyl butyral resin. A polyvinyl butyral resin is preferable. Specific examples of the polyvinyl acetal resin may include “denkabutyral 4000-2,” “denkabutyral 5000-A,” “denkabutyral 6000-C,” and “denkabutyral 6000-EP” available from Denki Kagaku Kogyo Kabushiki Kaisha, and S-LEC BH series, BX series (e.g., BX-5Z), KS series (e.g., KS-1), BL series, and BM series available from Sekisui Chemical Co., Ltd.

Specific examples of the polyimide resin may include “RIKACOAT SN20” and “RIKACOAT PN20” available from New Japan Chemical Co., Ltd. Specific examples of the polyimide resin may include modified polyimides such as a linear polyimide obtained by reaction of a difunctional hydroxyl-terminated polybutadiene, a diisocyanate compound, and a tetrabasic acid anhydride (polyimide described in Japanese Patent Application Laid-Open No. 2006-37083, which is incorporated herein by reference in its entirety), and a polysiloxane skeleton-containing polyimide (polyimide described in Japanese Patent Application Laid-Open Nos. 2002-12667 and 2000-319386, which are incorporated herein by reference in their entireties).

Specific examples of the polyamideimide resin may include “VYLOMAX HR11NN” and “VYLOMAX HR16NN” available from Toyobo Co., Ltd. Additional examples of the polyamideimide resin may include modified polyamideimides such as “KS9100” and “KS9300” (polysiloxane skeleton-containing polyamideimide) available from Hitachi Chemical Company, Ltd.

Specific examples of the polyethersulfone resin may include “PES5003P” available from Sumitomo Chemical Co., Ltd.

Specific examples of the polysulfone resin may include polysulfones “P1700” and “P3500” available from Solvay Advanced Polymers K.K.

Specific examples of the polyphenylene ether resin may include oligophenylene ether-styrene resin “OPE-2St1200” available from Mitsubishi Gas Chemical Company, Inc.

Among them, the phenoxy resin and polyvinyl acetal resin are preferable. In a preferred embodiment, the thermoplastic resin contains one or more selected from the group consisting of the phenoxy resin and the polyvinyl acetal resin.

When the resin composition contains a thermoplastic resin, the content of the thermoplastic resin is preferably 0.1% by mass or more, more preferably 0.2% by mass or more, and further preferably 0.3% by mass or more. The upper limit thereof is not particularly limited, and may be preferably 10% by mass or less, more preferably 5% by mass or less, and further preferably 3% by mass or less.

### (e) Curing Accelerator

Examples of the curing accelerator may include a phosphorus-based curing accelerator, an amine-based curing accelerator, an imidazole-based curing accelerator, a guanidine-based curing accelerator, a metallic curing accelerator, and an organic peroxide-based curing accelerator. A phosphorus-based curing accelerator, an amine-based curing accelerator, an imidazole-based curing accelerator, and a metallic curing accelerator are preferable, and an amine-based curing accelerator, an imidazole-based curing accelerator, and a metallic curing accelerator are more preferable. The curing accelerator may be used alone or in combination of two or more kinds thereof. As the curing accelerator, a commercially available product may be used.

Examples of the phosphorus-based curing accelerator may include triphenylphosphine, a phosphoniumborate compound, tetraphenylphosphonium tetraphenylborate, n-butylphosphonium tetraphenylborate, tetrabutylphosphonium decanoate, (4-methylphenyl)triphenylphosphonium thiocyanate, tetraphenylphosphonium thiocyanate, and butyltriphenylphosphonium thiocyanate. Triphenylphosphine and tetrabutylphosphonium decanoate are preferable.

Examples of the amine-based curing accelerator may include trialkylamine such as triethylamine and tributylamine, 4-dimethylaminopyridine, benzyldimethylamine, 2,4,6-tris(dimethylaminomethyl)phenol, and 1,8-diazabicyclo[5,4.0]undecene. 4-Dimethylaminopyridine and 1,8-diazabicyclo[5,4,0]-undecene are preferable.

Examples of the imidazole-based curing accelerator may include an imidazole compound such as 2-methylimidazole, 2-undecylimidazole, 2-heptadecylimidazole, 1,2-dimethylimidazole, 2-ethyl-4-methylimidazole, 1,2-dimethylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-undecylimidazole, 1-cyanoethyl-2-ethyl-4-methylimidazole, 1-cyanoethyl-2-phenylimidazole, 1-cyanoethyl-2-undecylimidazolium trimellitate, 1-cyanoethyl-2-phenylimidazolium trimellitate, 2,4-diamino-6-[2′-methylimidazolyl-(1′)]-ethyl-s-triazine, 2,4-diamino-6[2′-undecylimidazolyl-(1′)]-ethyl-s-triazine, 2,4-diamino-6-[2′-ethyl-4′-methylimidazolyl-(1′)]-ethyl-s-triazine, a 2,4-diamino-6-[2′-methylimidazolyl-(1¹)]-ethyl-s-triazine isocyanuric acid adduct, a 2-phenylimidazole isocyanuric acid adduct, 2-phenyl-4,5-dihydroxymethylimidazole, 2-phenyl-4-methyl-5-hydroxymethylimidazole, 2,3-dihydro-1H-pyrrolo [1,2-a]benzimidazole, 1-dodecyl-2-methyl-3-benzylimidazolium chloride, 2-methylimidazoline, and 2-phenylimidazoline; and an adduct of such imidazole compound and an epoxy resin. 2-Ethyl-4-methylimidazole and 1-benzyl-2-phenylimidazole are preferable.

As the imidazole-based curing accelerator, a commercially available product may be used. Examples thereof may include “P200-H50” available from Mitsubishi Chemical Corporation.

Examples of the guanidine-based curing accelerator may include dicyandiamide, 1-methylguanidine, 1-ethylguanidine, 1-cyclohexylguanidine, 1-phenylguanidine, 1-(o-tolyl)guanidine, dimethylguanidine, diphenylguanidine, trimethylguanidine, tetramethylguanidine, pentamethylguanidine, 1,5,7-triazabicyclo[4.4.0]dec-5-ene, 7-methyl-1,5,7-triazabicyclo[4.4.0]dec-5-ene, 1-methylbiguanide, 1-ethylbiguanide, 1-n-butylbiguanide, 1-n-octadecylbiguanide, 1,1-dimethylbiguanide, 1,1-diethylbiguanide, 1-cyclohexylbiguanide, 1-allylbiguanide, 1-phenylbiguanide, and 1-(o-tolyl)biguanide. Dicyandiamide and 1,5,7-triazabicyclo[4.4.0]dec-5-ene are preferable.

Examples of the metallic curing accelerator may include an organic complex and an organic salt of a metal such as cobalt, copper, zinc, iron, nickel, manganese, and tin. Specific examples of the organic metal complex may include an organic cobalt complex such as cobalt(II) acetylacetonate and cobalt(III) acetylacetonate, an organic copper complex such as copper(II) acetylacetonate, an organic zinc complex such as zinc(II) acetylacetonate, an organic iron complex such as iron(III) acetylacetonate, an organic nickel complex such as nickel(II) acetylacetonate, and an organic manganese complex such as manganese(II) acetylacetonate. Examples of the organic metal salt may include zinc octylate, tin octylate, zinc naphthenate, cobalt naphthenate, tin stearate, and zinc stearate.

Examples of the organic peroxide-based curing accelerator may include dicumyl peroxide, cyclohexanone peroxide, tert-butyl peroxybenzoate, methyl ethyl ketone peroxide, dicumyl peroxide, tert-bythyl cumyl peroxide, di-tert-butyl peroxide, diisopropylbenzene hydroperoxide, cumene hydroperoxide, and tert-butyl hydroperoxide. As the organic peroxide-based curing accelerator, a commercially available product may be used. Examples thereof may include “percumyl D” available from NOF corporation.

The content of the curing accelerator in the resin composition is not particularly limited, and is preferably 0.005% by mass to 3% by mass relative to 100% by mass of nonvolatile components in the epoxy resin and the curing agent.

### (f) Flame Retardant

Examples of the flame retardant may include an organic phosphorus-based flame retardant, an organic nitrogen-containing phosphorus compound, a nitrogen compound, a silicone-based flame retardant, and metal hydroxide. The flame retardant may be used alone or in combination of two or more kinds thereof.

As the flame retardant, a commercially available product may be used. Examples thereof may include “HCA-HQ” available from Sanko Co., Ltd., and “PX-200” available from Daihachi Chemical Industry Co., Ltd.

When the resin composition contains the flame retardant, the content of the flame retardant is not particularly limited, and is preferably 0.5% by mass to 20% by mass, more preferably 0.5% by mass to 15% by mass, and further preferably 0.5% by mass to 10% by mass.

### (g) Organic Filler

The resin composition may further contain (g) the organic filler in order to improve elongation. As the organic filler, any organic filler that may be used for forming an insulating layer of a printed wiring board may be used. Examples thereof may include rubber particles, polyamide fine particles, and silicone particles.

As the rubber particles, a commercially available product may be used. Examples thereof may include “EXL2655” available from The Dow Chemical Company, and “AC3816N” available from Aica Kogyo Company, Limited.

When the resin composition contains the organic filler, the content of the organic filler is preferably 0.1% by mass to 20% by mass, more preferably 0.2% by mass to 10% by mass, and further preferably 0.3% by mass to 5% by mass or 0.5% by mass to 3% by mass.

### (h) Other Additive

The resin composition may further contain other additive, if necessary. Examples of the other additive may include an organometallic compound such as an organic copper compound, an organic zinc compound, and an organic cobalt compound, and a resin additive such as a thickener, an antifoaming agent, a leveling agent, an adhesion-imparting agent, and a coloring agent.

In order to produce a flexible printed wiring board, it is preferable that the resin composition further contain a polyimide resin having a polybutadiene structure, a urethane structure, and an imide structure in the molecule and a phenol structure in the terminal ends of the molecule. When the resin composition contains the polyimide resin, the content of the polyimide resin is preferably 10% by mass to 85% by mass, more preferably 12% by mass to 50% by mass, and further preferably 15% by mass to 30% by mass.

Details of the polyimide can be used with reference to the description of International publication No. 2008/153208, which is incorporated herein by reference in its entirety.

In the adhesive sheet of the first embodiment, the lowest melt viscosity Y of the resin composition layer at 120° C. or higher is preferably 1,000 poises or more, more preferably 1,500 poises or more, and further preferably 2,000 poises or more, 2,500 poises or more, or 4,000 poises or more in order to suppress the occurrence of curing unevenness and undulation. The upper limit thereof is preferably 1,000,000 poises or less, more preferably 500,000 poises or less, and further preferably 400,000 poises or less, 50,000 poises or less, or 40,000 poises or less.

In the adhesive sheet of the second embodiment, the lowest melt viscosity of the resin composition layer at T1 (° C.) or higher is preferably 4,000 poises or more, more preferably 4,500 poises or more, further preferably 5,000 poises or more, and still more preferably 6,000 poises or more. The upper limit thereof is preferably 1,000,000 poises or less, more preferably 600,000 poises or less, and further preferably 100,000 poises or less, 50,000 poises or less, or 10,000 poises or less. When the lowest melt viscosity is 4,000 poises or more, the occurrence of curing unevenness and undulation can be suppressed.

Herein, the “lowest melt viscosity” of the resin composition layer is the lowest viscosity of the resin composition layer when the resin of the resin composition layer is melted. Specifically, when the resin composition layer is heated at a constant rate of temperature rise to melt the resin, the melt viscosity is decreased with increasing temperature at an initial stage and then the melt viscosity is increased with increasing temperature as the temperature becomes higher than a certain temperature. The “lowest melt viscosity” is a melt viscosity at the time when the melt viscosity becomes a minimum. The lowest melt viscosity and the lowest melt viscosity temperature of the resin composition layer can be measured by a dynamic viscoelasticity method.

The thickness of the resin composition layer is not particularly limited. In order to make a printed wiring board thinner, the thickness is preferably 5 μm to 100 μm, more preferably 10 μm to 90 μm, and further preferably 15 μm to 80 μm.

The adhesive sheet of the present invention also includes an adhesive sheet of an aspect that satisfies both the first and second embodiments. The adhesive sheet of such aspect is preferable. In the adhesive sheet according to such aspect that satisfies both the first and second embodiments, X((E_{AMD}−E_{BMD})+(E_{ATD}−E_{BTD})) in the support is 4 or less, the lowest melt viscosity of the resin composition layer at T1 (° C.) or higher is 4,000 poises or more, and the lowest melt viscosity Y of the resin composition layer at 120° C. or higher satisfies Y>2700X.

### Method for Producing Printed Wiring Board

A method for producing a printed wiring board of the first embodiment of the present invention includes the steps of (A) preparing an adhesive sheet including a support and a resin composition layer provided on the support, (B) laminating the adhesive sheet on an internal layer substrate so that the resin composition layer is in contact with the internal layer substrate, and (C) thermally curing the adhesive sheet by heating from T1 (° C.) to T2 (° C.), to form an insulating layer. In the method for producing a printed wiring board, the adhesive sheet is thermally cured so as to satisfy a relation of Y>2700X, wherein X represents a sum ((E_{AMD}−E_{BMD}) (E_{ATD}−E_{BTD})) of the difference (E_{AMD}−E_{BMD}) between the maximum expansion rate E_{AMD} (%) of the support in the MD direction during heating from T1 (° C.) to T2 (° C.) and the expansion rate E_{BMD} (%) of the support at T2 (° C.) at the end of heating and the difference (E_{ATD}−E_{BTD}) between the maximum expansion rate E_{ATD} (%) of the support in the TD direction during heating from T1 (° C.) to T2 (° C.) and the expansion rate E_{BTD} (%) of the support at T2 (° C.) at the end of heating and Y represents a lowest melt viscosity of the resin composition layer at 120° C. or higher.

A method for producing a printed wiring board of the second embodiment of the present invention includes the steps of (A) preparing an adhesive sheet having a support and a resin composition layer provided on the support, (B) laminating the adhesive sheet on an internal layer substrate so that the resin composition layer is in contact with the internal layer substrate, and (C) thermally curing the adhesive sheet by heating from T1 (° C.) to T2 (° C.), to form an insulating layer. In the method for producing a printed wiring board, the adhesive sheet is thermally cured so that a sum ((E_{AMD}−E_{BMD})+(E_{ATD}−E_{BTD})) of the difference (E_{AMD}−E_{BMD}) between the maximum expansion rate E_{AMD} (%) of the support in the MD direction during heating from T1 (° C.) to T2 (° C.) and the expansion rate E_{BMD} (%) of the support at T2 (° C.) at the end of heating and the difference (E_{ATD}−E_{BTD}) between the maximum expansion rate E_{ATD} (%) of the support in the TD direction during heating from T1 (° C.) to T2 (° C.) and the expansion rate E_{BTD} (%) of the support at T2 (° C.) at the end of heating is 4 or less and a lowest melt viscosity of the resin composition layer at T1 (° C.) or higher is 4,000 poises or more.

Each step in the first and second embodiments will be described below.

### Step (A)

In the step (A), an adhesive sheet having a support and a resin composition layer provided on the support is prepared.

The adhesive sheet is as described in “Adhesive Sheet” noted above. In the method for producing a printed wiring board of the first embodiment, it is preferable that the adhesive sheet of the first embodiment be prepared. In the method for producing a printed wiring board of the second embodiment, it is preferable that the adhesive sheet of the second embodiment be prepared.

The adhesive sheet can be produced, for example, by preparing a resin varnish in which a resin composition is dissolved in an organic solvent, applying the resin varnish to the support using a die coater or the like, and drying the resin varnish to form the resin composition layer on the support.

Examples of the organic solvent may include ketones such as acetone, methyl ethyl ketone, and cyclohexanone, acetate esters such as ethyl acetate, butyl acetate, cellosolve acetate, propylene glycol monomethyl ether acetate, and carbitol acetate, carbitols such as cellosolve and butyl carbitol, aromatic hydrocarbons such as toluene and xylene, and amide-based solvents such as dimethylforamide, dimethylacetamide, and N-methyl pyrrolidone. The organic solvent may be used alone or in combination of two or more kinds thereof.

The resin varnish may be dried by a publicly known drying method such as heating and blowing hot air. Although a drying condition is not particularly limited, the resin varnish is dried so that the content of the organic solvent in the resin composition layer (the remaining solvent content) is 10% by mass or less, and preferably 5% by mass or less. In order to improve the handleability of the resin composition layer and prevent an increase in the melt viscosity in an adhesive sheet form, the remaining solvent amount is preferably 0.5% by mass or more, and more preferably 1% by mass or more. When, for example, a resin varnish containing 30% by mass to 60% by mass of organic solvent is used, the resin varnish is dried at 50° C. to 150° C. for 3 minutes to 10 minutes, whereby a resin composition layer can be formed. However, these conditions vary depending on the boiling point of the solvent in the resin varnish.

In the adhesive sheet, a protective film that is the same film as the support described above can be further laminated onto a surface of the resin composition layer that is not in contact with the support (that is, a surface on a side opposite to the support). The thickness of the protective film is not particularly limited, and is, for example, 1 μm to 40 μm. By laminating the protective film, attachment of dust or the like or occurrence of scratch on the surface of the resin composition layer can be prevented. The adhesive sheet can be wound into a roll form and stored. In production of a printed wiring board, the adhesive sheet can be used by peeling off the protective film.

Step (B) In the step (B), the adhesive sheet is laminated on an internal layer substrate so that the resin composition layer is in contact with the internal layer substrate.

The “internal layer substrate” used in the step (B) refers mainly to: a substrate such as a glass epoxy substrate, a metal substrate, a polyester substrate, a polyimide substrate, a BT resin substrate and a thermosetting polyphenylene ether substrate; and a circuit substrate in which a patterned conductive layer (circuit) is formed on one side or both sides of the above substrate. The “internal layer substrate” in the present invention also includes a layered structure that is an intermediate product having one or more insulating layers and/or conductive layers on which an insulating layer and/or a conductive layer is further to be formed in the production of a printed wiring board.

The lamination (bonding) of the adhesive sheet and the internal layer substrate can be carried out by, for example, thermal pressing the adhesive sheet to the internal layer substrate from the support side. Examples of a member used for thermal pressing the adhesive sheet to the internal layer substrate (hereinafter referred to as a “thermal pressing member”) may include a heated metal plate such as a stainless (SUS) flat panel and a heated metal roll (SUS roll). The thermal pressing member is preferably pressed against the adhesive sheet in a state that an elastic material such as heat resistant rubber intervenes therebetween so as to allowing the adhesive sheet to sufficiently follow the surface irregularities of the internal layer substrate, instead of directly pressing the thermal pressing member against the adhesive sheet.

The temperature during thermal pressing is preferably in a range of 80° C. to 160° C., more preferably in a range of 90° C. to 140° C., and further preferably in a range of 100° C. to 120° C. The pressure during thermal pressing is preferably in a range of 0.098 MPa to 1.77 MPa, and more preferably in a range of 0.29 MPa to 1.47 MPa. The time during thermal pressing is preferably in a range of 20 seconds to 400 seconds, and more preferably in a range of 30 seconds to 300 seconds. It is preferable that the bonding of the adhesive sheet and the internal layer substrate be performed under a reduced pressure of 26.7 hPa or lower.

The bonding of the adhesive sheet and the internal layer substrate can be performed using a commercially available vacuum laminator. Examples of the commercially available vacuum laminator may include a vacuum pressure laminator manufactured by Meiki Co., Ltd., and a vacuum applicator manufactured by Nikko-Materials Co., Ltd.

After the adhesive sheet is bonded to the internal layer substrate, the laminated adhesive sheet may be subjected to a smoothing treatment, for example, by pressing the thermal pressing member from the support side under normal pressure (atmospheric pressure). A pressing condition for the smoothing treatment may be the same as the thermal pressing condition for the lamination described above. In the smoothing treatment, a commercially available vacuum laminator may be used. The laminating and the smoothing treatment may be performed continuously using the commercially available vacuum laminator.

### Step (C)

In the step (C), the adhesive sheet is thermally cured by heating from T1 (° C.) to T2 (° C.), to form an insulating layer. In the step (C), a process of heating from T1 (° C.) to T2 (° C.) is not particularly limited as long as a heating condition during thermal curing can be adjusted so as to control expansion and contraction of the support. The thermal curing may be in one step or two steps.

The condition for thermal curing is determined according to characteristics of the selected support and the resin composition layer. The condition may be a condition that is usually used in formation of an insulating layer of a printed wiring board.

A condition for thermally curing the resin composition layer varies depending on the composition of the resin composition layer. For example, the curing temperature is in a range of 50° C. to 240° C. or 150° C. to 240° C., preferably 155° C. to 230° C., more preferably 160° C. to 220° C., further preferably 170° C. to 210° C., and still more preferably 180° C. to 200° C. The curing time may be in a range of 5 minutes to 100 minutes, preferably 10 minutes to 80 minutes, and more preferably 10 minutes to 50 minutes. The curing condition may be determined in consideration of flattening the resin composition layer through self alignment by melting. The thermal curing may be performed under any of normal pressure, reduced pressure, and increased pressure.

In one preferred embodiment, thermal curing in the step (C) is performed by heating the adhesive sheet at T1 (° C.) and then at T2 (° C.). It is preferable that the step (C) includes the following steps of:

i) heating the resin composition layer at T1 (° C.) (50° C.≦T1≦150° C.); and

ii) heating the heated resin composition layer at T2 (° C.) (150° C.≦T2≦240° C.). That is, in the step (C), it is preferable to heat in two steps.

In the heating of i), T1 (° C.) varies depending on the composition of the resin composition layer, and preferably satisfies a relation of 50° C.≦T1≦150° C., more preferably 80° C.≦T1≦150° C., and further preferably 120° C.≦T1≦150° C.

After heating to T1 (° C.), the temperature of T1 (° C.) may be held for a given time. The holding time at T1 (° C.) varies depending on a temperature of T1, and it is preferably 10 minutes to 150 minutes, more preferably 15 minutes to 60 minutes, and further preferably 20 minutes to 40 minutes.

Although the heating of i) may be performed under normal pressure, reduced pressure, or increased pressure, the heating is performed under the pressure preferably in a range of 0.075 mmHg to 3,751 mmHg (0.1 hPa to 5,000 hPa), and more preferably in a range of 1 mmHg to 1,875 mmHg (1.3 hPa to 2,500 hPa).

In the thermal curing of ii), T2 (° C.) varies depending on the composition of the resin composition layer, and preferably satisfies a relation of 150° C.≦T2≦240° C., more preferably 155° C.≦T2≦200° C., and further preferably 170° C.≦T2≦180° C.

The thermal curing time at T2 (° C.) varies depending on a value of T2, and is preferably 5 minutes to 100 minutes, more preferably 10 minutes to 80 minutes, and further preferably 10 minutes to 50 minutes.

The thermal curing of ii) may be performed under normal pressure, reduced pressure, or increased pressure. It is preferable that the thermal curing be performed under the same pressure as that described in i).

T1 (° C.) and T2 (° C.) preferably satisfy a relation of 10° C.≦T2−T1≦150° C., more preferably 15° C.≦T2−T1≦140° C., further preferably 15° C.≦T2−T1≦120° C., and particularly preferably 15° C.≦T2−T1≦100° C.

Between the heating of i) and the thermal curing of ii), the resin composition layer may be allowed to cool once. Alternatively, between the heating of i) and the thermal curing of ii), the resin composition layer may not be allow to cool. In one preferred embodiment, the step (C) further includes a step of increasing a temperature from T1 (° C.) to T2 (° C.) between the heating of i) and thermal curing of ii). In such an embodiment, the temperature increasing rate from T1 (° C.) to T2 (° C.) is preferably 1.5° C./min to 30° C./min, more preferably 2° C./min to 30° C./min, further preferably 4° C./min to 20° C./min, and still more preferably 4° C./min to 10° C./min. The resin composition layer may begin to be thermally cured during increasing the temperature.

When thermal curing is performed by heating in one step, T1 (° C.) varies depending on the composition of the resin composition layer, and preferably satisfies a relation of 0° C.≦T1≦50° C., more preferably 5° C.≦T1≦40° C., and further preferably 10° C.≦T1≦30° C.

The thickness of an insulating layer may be the same as the thickness of the resin composition layer. A preferable range of the thickness of an insulating layer may be also the same as the preferable range of thickness of the resin composition layer.

### Step (D)

After completion of the step (C), a step (D) of removing the support may be performed.

The support can be removed by peeling through any conventionally known suitable method. The support may be removed mechanically using an automated peeling device. According to the step (D), a surface of the formed insulating layer is exposed.

When a printed wiring board is produced, a step (E) of perforating the insulating layer, a step (F) of roughening the insulating layer, and a step (G) of forming a conductive layer on the surface of the insulating layer may be further performed. These steps (E) to (G) may be performed by any methods that are known to those skilled in the art in the production of a printed wiring board.

The step (E) is a step of perforating the insulating layer, whereby via-holes or through holes can be formed in the insulating layer. For example, a step of perforating may be performed using a drill, a laser (a carbon dioxide gas laser, a YAG laser, etc.), plasma, or the like. The step (E) may be performed between the steps (C) and (D) or after the step (D).

The step (F) is a step of roughening the insulating layer. The procedure and condition for roughening are not particularly limited, and publicly known procedure and condition that are generally used in formation of an insulating layer of a printed wiring board may be used. At the step (F), the insulating layer may be roughened by a swelling treatment with a swelling solution, a roughening treatment with an oxidant, and a neutralization treatment with a neutralization solution in this order. The swelling solution is not particularly limited, and examples thereof may include an alkaline solution and a surfactant solution. An alkaline solution is preferable. As the alkaline solution, a sodium hydroxide solution and a potassium hydroxide solution are preferable. Examples of a commercially available swelling solution may include “Swelling Dip Securiganth P” and “Swelling Dip Securiganth SBU” available from Atotech Japan K. K. The swelling treatment with the swelling solution is not particularly limited, and for example, can be performed by immersing the insulating layer into the swelling solution at 30° C. to 90° C. for 1 minute to 20 minutes. The oxidant is not particularly limited, and examples thereof may include an alkaline permanganate solution in which potassium permanganate or sodium permanganate is dissolved in an aqueous solution of sodium hydroxide. The roughening treatment with the oxidant such as the alkaline permanganate solution is preferably performed by immersing the insulating layer into an oxidant solution that is heated at 60° C. to 80° C. for 10 minutes to 30 minutes. The concentration of peiinanganate in the alkaline permanganate solution is preferably 5% by mass to 10% by mass. Examples of a commercially available oxidant may include an alkaline permanganate solution such as “Concentrate Compact CP” and “Dosing Solution Securiganth P” available from Atotech Japan K.K. It is preferable that the neutralization solution be an acidic aqueous solution. Examples of a commercially available product may include “Reduction Solution Securiganth P” available from Atotech Japan K.K. The treatment with the neutralization solution may be performed by immersing the insulating layer a surface of which has been roughened with the oxidant solution into the neutralization solution at 30° C. to 80° C. for 5 minutes to 30 minutes.

The step (G) is a step of forming a conductive layer on the surface of the insulating layer.

A conductive material used for the conductive layer is not particularly limited. In a preferred embodiment, the conductive layer includes one or more metals selected from the group consisting of gold, platinum, palladium, silver, copper, aluminum, cobalt, chromium, zinc, nickel, titanium, tungsten, iron, tin, and indium. The conductive layer may be a single metal layer or an alloy layer. Examples of the alloy layer may include layers formed of an alloy of two or more metals selected from the above-described group such as a nickel-chromium alloy, a copper-nickel alloy, and a copper-titanium alloy. In particular, from the viewpoints of ease of forming the conductive layer, cost, and ease of patterning, the conductive layer is preferably a single metal layer of chromium, nickel, titanium, aluminum, zinc, gold, palladium, silver or copper, or an alloy layer of a nickel-chromium alloy, a copper-nickel alloy or a copper-titanium alloy; more preferably a single metal layer of chromium, nickel, titanium, aluminum, zinc, gold, palladium, silver or copper, or an alloy layer of a nickel-chromium alloy; and further preferably a single metal layer of copper.

The conductive layer may have a single-layer structure or a multi-layer structure in which two or more layers of single metal layer or alloy layer formed of different kinds of metals or alloys are layered. When the conductive layer has a multi-layer structure, it is preferable that a layer in contact with the insulating layer be a single metal layer of chromium, zinc or titanium or an alloy layer of nickel-chromium alloy.

The thickness of the conductive layer varies depending on a desired design of a printed wiring board, and is generally 3 μm to 35 μm, and preferably 5 μm to 30 μm.

The conductive layer may be formed by plating. For example, a conductive layer having a desired wiring pattern can be formed by plating the surface of the insulating layer through a conventionally known technique such as a semi-additive method and a full-additive method. Hereinafter, an example of forming the conductive layer by the semi-additive method will be described.

Firstly, a plating seed layer is formed on the surface of the insulating layer by electroless plating. Subsequently, onto the formed plating seed layer, a mask pattern is formed that exposes a portion of the plating seed layer corresponding to a desired wiring pattern. A metal layer is formed on the exposed plating seed layer by electrolytic plating, and then the mask pattern is removed. After that, an unnecessary plating seed layer can be removed by etching or the like to form a conductive layer having a desired wiring pattern.

According to a printed wiring board produced by the method for producing a printed wiring board of the present invention, undulation or the like of the insulating layer can be suppressed. Specifically, a printed wiring board in which variation in the thickness of the insulating layer is suppressed is provided. The undulation is preferably 1 μm or less, more preferably 0.8 μm or less, and further preferably 0.5 μm or less. The lower limit of the variation is not particularly limited, and may be 0.01 μm or more. The undulation may be measured in accordance with a method described in “Measurement of Undulation” described below.

According to the printed wiring board produced by the method for producing a printed wiring board of the present invention, curing unevenness after formation of the insulating layer is suppressed, and the suppression is confirmed by visual observation. Specifically, a printed wiring board in which curing unevenness is suppressed is provided. The curing unevenness may be measured in accordance with a method described in “Evaluation of Surface of Insulating Layer” described below.

### Semiconductor Device

A semiconductor device provided with a printed wiring board can be produced using the printed wiring board obtained by the production method of the present invention.

Examples of the semiconductor device may include various semiconductor devices used in electrical products such as a computer, a cellular phone, a digital camera and a television, and vehicles such as a motorcycle, an automobile, a train, a ship and an airplane.

The semiconductor device of the present invention can be produced by mounting a part (semiconductor chip) on a conducting part of the printed wiring board. The “conducting part” is a “part for conducting an electric signal in the printed wiring board,” which may be positioned on a surface or an embedded part. The semiconductor chip is not particularly limited as long as it is an electric circuit element made of a semiconductor as a material.

A method for mounting the semiconductor chip in production of the semiconductor device of the present invention is not particularly limited as long as the semiconductor chip effectively functions. Specific examples of the method may include a wire bonding mounting method, a flip-chip mounting method, a mounting method using a bumpless build-up layer (BBUL), a mounting method using an anisotropic conductive film (ACF), and a mounting method using a non-conductive film (NCF). The “method of mounting by bumpless build-up layer (BBUL)” is “a mounting method in which a semiconductor chip is embedded directly in a concave portion of a printed wiring board, followed by connecting the semiconductor chip to the wiring on the printed wiring board.”

### Layered Body

A layered body of the present invention includes an internal layer substrate, an insulating layer provided on the internal layer substrate, and a support being in contact with the insulating layer. In the layered body, variation in the thickness of the insulating layer is 1 μm or less in a region except for 5% of the dimension of the support from edge portions of the support.

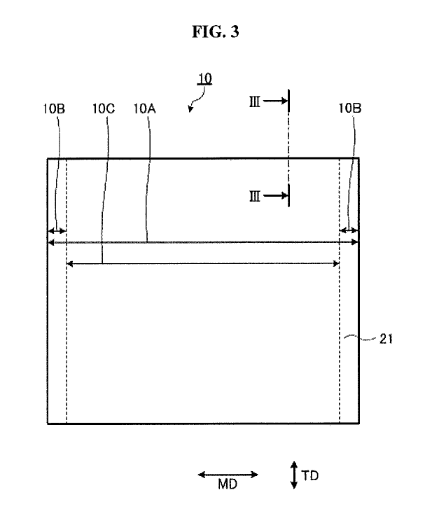

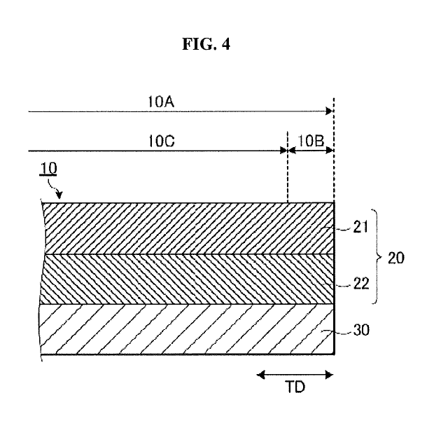

A configuration example of the layered body of the present invention will be described with reference to FIGS. 3 and 4. FIG. 3 is a schematic plan view of the layered body. FIG. 4 is a schematic view of an end surface of the layered body that is cut along chain line of FIG. 3.

As shown as an example in FIGS. 3 and 4, a layered body 10 has an internal layer substrate 30, an insulating layer 22 provided on the internal layer substrate 30, and a support 21 being in contact with the insulating layer 22.

In this layered body 10, the insulating layer 22 formed on the internal layer substrate 30 means an insulating layer newly formed from an adhesive sheet 20 described above. The insulating layer 22 in the layered body 10 is not limited to a single layer, and may include an aspect in which two or more insulating layers 22 are layered on one surface of the internal layer substrate 30. When the layered body 10 includes two or more insulating layers, at least one of the two or more insulating layers may be formed by laminating an adhesive sheet including the support 21 having the characteristics described above on the internal layer substrate 30, thermally curing a resin composition layer, and peeling and removing the support 21.

In the layered body 10, the variation in thickness of the insulating layer is 1 μm or less, preferably 0.8 μm or less, and more preferably 0.5 μm or less in a region except for 5% of the dimension of the support from the edge portions of the support of the layered body 10. The lower limit of the variation is not particularly limited, and may be 0.01 μm or more.

Herein, the “region except for 5% of the dimension of the support from the edge portions of the support” means a region where edge portions 10B of the layered body 10 are excluded as shown as an example in FIGS. 3 and 4. Specifically, the range means a region where both the edge portions 10B are excluded from a dimension (length) 10A of the support (region of a central part 10C), and the length of the edge portions 10B is 2.5% of the dimension 10A of the support. FIGS. 3 and 4 show the dimension (length) 10A of the support only in the MD direction, but the dimension of the support in the TD direction is the same as that in the MD direction.

Other features of the invention will become apparent in the course of the following descriptions of exemplary embodiments which are given for illustration of the invention and are not intended to be limiting thereof.

### EXAMPLES

In the following description, “part” and “%” represent “part by mass” and “% by mass,” respectively, unless otherwise specified.

### Example 1

### Production of Adhesive Sheet

Pre-Heating condition of Support

A pre-heating condition used in preparation of supports in the following Examples and Comparative Examples are shown in Table 1. In Table 1, “tension” means a tension applied to the supports in the TD direction.

TABLE 1

| Pre-heating condition | 1 | 2 | 3 |
|---|---|---|---|
| Heating Temp. (° C.) | 130 | 170 | 170 |
| Heating time (min) | 30 | 10 | 10 |
| Tension (gf/cm²) | 20 | 2 | 30 |

### (1) Preparation of Support

A PET film with an alkyd resin-based release layer (“AL5” available from LINTEC Corporation, thickness: 38 μm, the PET film may be hereinafter referred to as a “release PET film”) was heated in an air atmosphere at normal pressure under the pre-heating condition 2 described in Table 1 while the tension was applied in the TD direction, thus obtaining a support.

### (2) Preparation of Resin Varnish A

30 Parts of a biphenyl-type epoxy resin (epoxy equivalent weight: about 290, “NC3000H” available from Nippon Kayaku Co., Ltd.), 5 parts of a tetrafunctional naphthalene-type epoxy resin (epoxy equivalent weight: 162, “HP-4700” available from DIC corporation), 15 parts of a liquid bisphenol A-type epoxy resin (epoxy equivalent weight: 180, “jER828EL” available from Mitsubishi Chemical Corporation), and 2 parts of a phenoxy resin (weight average molecular weight: 35,000, “YL7553BH30” available from Mitsubishi Chemical Corporation, methyl ethyl ketone (MEK) solution containing 30% by mass of solid content) were dissolved in a mixed solvent of 8 parts of MEK and 8 parts of cyclohexanone under heating and stirring. In the mixture, 32 parts of a triazine skeleton-containing phenol novolac-based curing agent (phenolic hydroxyl equivalent weight: about 124, “LA-7054” available from DIC corporation, MEK solution containing 60% by mass of a non-volatile component), 0.2 parts of a phosphorus-based curing accelerator (“TBP-DA” available from Hokko Chemical Industry Co., Ltd., tetrabutylphosphonium decanoate), 160 parts of spherical silica (“SOC2” available from Admatechs Company Limited, average particle diameter: 0.5 μm) surface-treated with an aminosilane-based coupling agent (“KBM573” available from Shin-Etsu Chemical Co., Ltd.), and 2 parts of a polyvinyl butyral resin solution (weight average molecular weight: 27,000, glass transition temperature: 105° C., “KS−1” available from Sekisui Chemical Co., Ltd., a mixed solution of ethanol and toluene at a mass ratio of 1:1 that contains 15% by mass of a non-volatile component) were mixed. The mixture was dispersed uniformly using a high-speed mixer to prepare a resin varnish. The content of the inorganic filler (spherical silica) was 69.5% by mass relative to a total mass of the non-volatile components being 100% by mass in the resin varnish.

### (3) Production of Adhesive Sheet

The resin varnish A prepared in (2) above was uniformly applied to the release layer of the support prepared in (1) above using a die coater and dried at 80 to 120° C. (100° C. on average) for 6 minutes to form a resin composition layer. The thickness of the resultant resin composition layer was 40 μm, and the amount of the remaining solvent was about 2% by mass. Next, while a polypropylene film (thickness: 15 μm) used as a protective film was laminated onto the resin composition layer, the resultant film was wound into a roll form. The obtained adhesive sheet in a roll form was cut to a width of 507 mm, thus obtaining an adhesive sheet 1 with a dimension of 507 mm×336 mm.

### Preparation of Samples for Evaluation and Measurement

### (1) Preparation of Internal Layer Circuit Substrate

Both surfaces of a double-sided copper clad layered body with an epoxy resin-glass cloth base material (thickness of copper foil: 18 μm, thickness of substrate: 0.8 mm, “R1515A” manufactured by Panasonic Electric Works Co., Ltd.) were immersed into “CZ8100” available from Mec Co., Ltd. Thus, the copper surface was subjected to a roughening treatment.

### (2) Lamination of Adhesive Sheet

The adhesive sheet 1 prepared was subjected to a lamination treatment on both sides of the internal layer circuit substrate using a batch-type vacuum pressure laminator (“MVLP-500” manufactured by Meiki Co., Ltd.) so that the resin composition layer was in contact with the internal layer circuit substrate. The lamination treatment was performed by reducing the pressure for 30 seconds to an air pressure of 13 hPa or less and then pressing for 30 seconds at 100° C. and a pressure of 0.74 MPa. The adhesive sheet 1 was laminated after peeling the protective film.

### (3) Thermal Curing of Resin Composition Layer

After the lamination of adhesive sheet 1, the resin composition layer was thermally cured, while the support being attached thereto, under the heating condition 2 among the heating conditions in two steps including temperatures T1 (° C.) and T2 (° C.) described in the following table (aspect of FIG. 1), thus forming an insulating layer. The onset temperature of heating was 20° C. (room temperature) and the temperature was increased at 8° C./min. The thickness of the resultant insulating layer on an internal layer circuit was 40 μm.

TABLE 2

| | Condition | 1 | 2 | 3 | 4 | 5 | 6 | 7 | 8 |
|---|---|---|---|---|---|---|---|---|---|
| 1st step | Temperature (° C.) | 80 | 100 | 120 | 80 | 80 | 100 | 120 | 150 |
| | Temperature increasing rate (° C./min) | 8 | 8 | 8 | 8 | 8 | 8 | 8 | 8 |
| | Holding time (min) | 30 | 30 | 30 | 30 | 60 | 30 | 30 | 30 |
| 2nd step | Temperature T2 (° C.) | 180 | 180 | 180 | 170 | 170 | 170 | 170 | 170 |
| | Temperature increasing rate (° C./min) | 8 | 8 | 8 | 8 | 8 | 8 | 8 | 8 |
| | Holding time (min) | 30 | 30 | 30 | 30 | 30 | 30 | 30 | 30 |

### Example 2

A sample for evaluation and measurement was prepared in the same manner as in Example 1 except that the heating condition 2 of the resin composition layer in Example 1 was changed to a heating condition 3.

### Example 3

A sample for evaluation and measurement was prepared in the same manner as in Example 1 except that the resin varnish A was changed to the following resin varnish B, the heating condition 2 was changed to a heating condition 5, and the pre-heating condition 2 of the support was changed to a pre-heating condition 1.

### Preparation of Resin Varnish B

28 Parts of a liquid bisphenol A type epoxy resin (epoxy equivalent weight: 180, “jER828EL” available from Mitsubishi Chemical Corporation) and 28 parts of a tetrafunctional naphthalene-type epoxy resin (epoxy equivalent weight: 162, “HP-4700” available from DIC corporation) were dissolved in a mixed solvent of 15 parts of methyl ethyl ketone (hereinafter abbreviated as “MEK”) and 15 parts of cyclohexanone under heating and stirring. In the mixture, 110 parts of a naphthol-based curing agent having a novolac structure (phenolic hydroxyl equivalent weight: 215, “SN485” available from Nippon Steel & Sumikin Chemical Co., Ltd., MEK solution containing 50% of solid content), 0.1 parts of a curing accelerator (“2E4MZ” available from Shikoku Chemicals Corporation, 2-phenyl-4-methylimidazole), 70 parts of spherical silica (“SO-C2” available from Admatechs Company Limited, average particle diameter: 0.5 μm), and 35 parts of a polyvinyl butyral resin solution (“KS-1” available from Sekisui Chemical Co., Ltd., weight average molecular weight: 27,000, glass transition temperature: 105° C., mixed solution of ethanol and toluene at a mass ratio of 1:1 that contains 15% of solid content) were mixed. The mixture was dispersed uniformly using a high-speed mixer to prepare a resin varnish. The content of the inorganic filler in the resin varnish was 38% by mass relative to 100% by mass of nonvolatile components in the resin varnish. A ratio of (the total number of epoxy group in the epoxy resin): (the total number of reaction group in the curing agent) was 1:0.78.

### Example 4

A sample for evaluation and measurement was prepared in the same manner as in Example 3 except that the heating condition 5 in Example 3 was changed to a heating condition 6.

### Example 5

A sample for evaluation and measurement was prepared in the same manner as in Example 3 except that the heating condition 5 in Example 3 was changed to a heating condition 7.

### Example 6

A sample for evaluation and measurement was prepared in the same manner as in Example 3 except that the heating condition 5 in Example 3 was changed to a heating condition 8.

### Example 7

A sample for evaluation and measurement was prepared in the same manner as in Example 3 except that the heating condition 5 in Example 3 was changed to a heating condition 4.

### Comparative Example 1

A sample for evaluation and measurement was prepared in the same manner as in Example 1 except that the heating condition 2 in Example 1 was changed to a heating condition 1.

### Comparative Example 2

A sample for evaluation and measurement was prepared in the same manner as in Example 3 except that the heating condition 5 in Example 3 was changed to the heating condition 6, and the pre-heating condition 1 of the support was changed to a pre-heating condition 3.

### Measurement of Expansion Rate of Support

### Measurement of Expansion and Contraction Ratios of Support in TD Direction

Rectangular test pieces with a dimension of 20 mm×4 mm were cut from the supports prepared in Examples and Comparative Examples so that the TD direction of each support was a direction of the long side. For each test piece, the expansion rate during the whole process of heating treatment was measured using a thermomechanical analysis apparatus (“TMA-SS6100” manufactured by Seiko Instruments Inc.) under a heating condition in two steps including heating at temperatures T1 (° C.) and T2 (° C.) described in the above table while the test piece was pressed in an air atmosphere at a load of 9.8 mmN. The maximum expansion rate E_{ATD} in the TD direction during heating from T1 (° C.) to T2 (° C.) and the expansion rate E_{BTD} (%) at the end of heating were determined.

For each support prepared in Examples and Comparative Examples, a difference (E_{ATD}−E_{BTD}) between the maximum expansion rate E_{ATD} and the expansion rate E_{BTD} was determined.

### Measurement of Expansion and Contraction Ratios of Support in MD Direction

Test pieces with a dimension of 20 mm×4 mm were cut from the supports prepared in Examples and Comparative Examples so that each test piece had its long side in the MD direction. For each test piece, the maximum expansion rate E_{AMD} in the MD direction during heating from T1 (° C.) to T2 (° C.) and the expansion rate E_{BMD} (%) at the end of heating were determined in the same manner as described above.

For each support prepared in Examples and Comparative Examples, a difference (E_{AMD}−E_{BMD}) between the maximum expansion rate E_{AMD} and the expansion rate E_{BMD} was determined. (E_{AMD}−E_{BMD}) was added to (E_{ATD}−E_{BTD}) to calculate a displacement amount X of the support.

### Measurement of Lowest Melt Viscosity

For the resin composition layer of the adhesive sheet prepared in each of Examples and Comparative Examples, the melt viscosity was measured using a dynamic viscoelasticity measurement device (“Rheosol-G3000” manufactured by UBM Co., Ltd.). For 1 g of the resin composition as a sample, the dynamic viscoelasticity was measured using a parallel plate with a diameter of 18 mm under a measurement condition in which the measurement temperature interval was 2.5° C., the vibration was 1 Hz, and the strain was 1° under a heating condition including a measurement onset temperature of 60° C., a temperature increasing rate of 8° C./min, and two steps including heating at T1 (° C.) and T2 (° C.) described in the above table. The low viscosity (poise) at T1 (° C.) or higher was confirmed. The lowest melt viscosity (poise) Y at 120° C. or higher was also confirmed.

### Measurement of Undulation

A surface of the insulating layer in the sample for evaluation and measurement prepared in each of Examples and Comparative Examples was measured in a measurement region of 121 μm×92 μm in a VSI contact mode with a 50-times lens using a non-contact type surface roughness meter (“WYKO GT-X3” manufactured by Veeco Instruments Inc.). The undulation (μm) was determined from the obtained values (difference between maximum height and minimum height of the insulating layer). When curing unevenness was generated in each insulating layer, measurement was performed at three parts where curing unevenness was generated (except for 5% of dimension of the insulating layer from edge portions of the insulating layer). When curing unevenness was not generated, measurement was performed at three randomly selected parts except for 5% of dimension of the insulating layer from edge portions of the insulating layer.

### Evaluation of Surface of Insulating Layer

The surface of the insulating layer was comprehensively evaluated by visual observation after a heating treatment and measurement of the undulation as mentioned above.

A case where the region except for 5% from the edge portions of the support satisfied all the following conditions was determined to be excellent to be marked with a symbol of “++,” a case where the region satisfied any one of the conditions was determined to be good to be marked with a symbol of “+,” and a case where the region did not satisfy all the conditions was determined to be problematic to be marked with a symbol of “−.”.

Conditions:

Curing unevenness was not confirmed after formation of the insulating layer by visual observation.

Any undulation exceeding 1.0 μM was not generated after formation of the insulating layer.

TABLE 3

| | | | Example | | | | |
|---|---|---|---|---|---|---|---|
| | | | 1 | 2 | 3 | 4 | 5 |
| Pre-heating condition of support | | | 2 | 2 | 1 | 1 | 1 |
| Resin composition layer | | Resin varnish | A | A | B | B | B |
| | | Thickness (μm) | 40 | 40 | 40 | 40 | 40 |
| Heating | Heating condition | | 2 | 3 | 5 | 6 | 7 |
| condition | 1st step | Temperature T1(° C.) | 100 | 120 | 80 | 100 | 120 |
| of support/ | | Temperature increasing rate (° C./min) | 8 | 8 | 8 | 8 | 8 |
| resin | | Holding time (min) | 30 | 30 | 60 | 30 | 30 |
| composition | 2nd step | Temperature T2(° C.) | 180 | 180 | 170 | 170 | 170 |
| layer | | Temperature increasing rate (° C./min) | 8 | 8 | 8 | 8 | 8 |
| | | Holding time (min) | 30 | 30 | 30 | 30 | 30 |
| Expansion | TD direction | Maximum expansion rate E_{ATD} (%) | 0.3 | 0.1 | 0 | −0.2 | −0.3 |
| rate of | | Expansion rate at end of heating E_{BTD} (%) | −1.6 | −1.7 | −0.7 | −0.7 | −0.7 |
| support | | E_{ATD} − E_{BTD} (%) | 1.9 | 1.8 | 0.7 | 0.5 | 0.4 |
| | MD direction | Maximum expansion rate E_{AMD} (%) | −0.1 | −0.3 | 0 | −0.2 | −0.2 |
| | | Expansion rate at end of heating E_{BTD} (%) | −1.7 | −1.7 | −0.9 | −0.9 | −0.8 |
| | | E_{AMD} − E_{BMD} (%) | 1.6 | 1.5 | 0.9 | 0.7 | 0.6 |

| | | | | | |
|---|---|---|---|---|---|
| (E_{ATD} − E_{BTD}) + (E_{AMD} − E_{BMD}) = X | 3.5 | 3.2 | 1.6 | 1.2 | 0.9 |
| 2700X | 9450 | 8640 | 4320 | 3240 | 2430 |

| Lowest melt viscosity (Poise) | Lowest melt viscosity at T1 or higher | 9900 | 78000 | 6300 | 10800 | 43100 |
|---|---|---|---|---|---|---|
| | Lowest melt viscosity at 120° C. or higher = Y | 9900 | 73000 | 6300 | 10800 | 43100 |
| Undulation (μm) | | 0.4 | 0.3 | 0.2 | 0.2 | 0.3 |
| Evaluation of surface of insulating layer | Curing unevenness after formation of insulating layer | None | None | None | None | None |
| | Comprehensive evaluation | ++ | ++ | ++ | ++ | ++ |

| | | | Example | | Comparative Example | |
|---|---|---|---|---|---|---|
| | | | 6 | 7 | 1 | 2 |
| Pre-heating condition of support | | | 1 | 1 | 2 | 3 |
| Resin composition layer | | Resin varnish | B | B | A | B |
| | | Thickness (μm) | 40 | 40 | 40 | 40 |
| Heating | Heating condition | | 8 | 4 | 1 | 6 |
| condition | 1st step | Temperature T1(° C.) | 150 | 80 | 80 | 100 |
| of support/ | | Temperature increasing rate (° C./min) | 8 | 8 | 8 | 8 |
| resin | | Holding time (min) | 30 | 30 | 30 | 30 |
| composition | 2nd step | Temperature T2(° C.) | 170 | 170 | 180 | 170 |
| layer | | Temperature increasing rate (° C./min) | 8 | 8 | 8 | 8 |
| | | Holding time (min) | 30 | 30 | 30 | 30 |
| Expansion | TD direction | Maximum expansion rate E_{ATD} (%) | −0.4 | 0.1 | 0.4 | 0.1 |
| rate of | | Expansion rate at end of heating E_{BTD} (%) | −0.7 | −0.5 | −1.5 | −2.8 |
| support | | E_{ATD} − E_{BTD} (%) | 0.3 | 0.6 | 1.9 | 2.8 |
| | MD direction | Maximum expansion rate E_{AMD} (%) | −0.6 | 0.1 | 0.1 | 0.1 |
| | | Expansion rate at end of heating E_{BTD} (%) | −1.1 | −0.8 | −1.6 | −1.3 |
| | | E_{AMD} − E_{BMD} (%) | 0.5 | 0.9 | 1.7 | 1.4 |

| | | | | |
|---|---|---|---|---|
| (E_{ATD} − E_{BTD}) + (E_{AMD} − E_{BMD}) = X | 0.8 | 1.5 | 3.6 | 4.2 |
| 2700X | 2160 | 4050 | 9720 | 11340 |

| Lowest melt viscosity (Poise) | Lowest melt viscosity at T1 or higher | 587000 | 4700 | 3400 | 10800 |
|---|---|---|---|---|---|
| | Lowest melt viscosity at 120° C. or higher = Y | 2500 | 4700 | 3400 | 10800 |
| Undulation (μm) | | 0.2 | 0.5 | 1.5 | 2.1 |
| Evaluation of surface of insulating layer | Curing unevenness after formation of insulating layer | None | Presence | Presence | Presence |

| | | | | |
|---|---|---|---|---|
| Comprehensive evaluation | ++ | + | − | − |

Where a numerical limit or range is stated herein, the endpoints are included. Also, all values and subranges within a numerical limit or range are specifically included as if explicitly written out.

As used herein the words “a” and “an” and the like carry the meaning of “one or more.”

Obviously, numerous modifications and variations of the present invention are possible in light of the above teachings. It is therefore to be understood that, within the scope of the appended claims, the invention may be practiced otherwise than as specifically described herein.

All patents and other references mentioned above are incorporated in full herein by this reference, the same as if set forth at length.

The invention claimed is:

1. A method for producing a printed wiring board, comprising:
(A) preparing an adhesive sheet comprising a support and a resin composition layer provided on said support;
(B) laminating said adhesive sheet on an internal layer substrate so that said resin composition layer is in contact with said internal layer substrate; and
(C) thermally curing said adhesive sheet by heating from T1 (° C.) to T2 (° C.), to form an insulating layer, wherein
the thermally curing is performed so as to satisfy a relation of Y>2700X, in which X is a sum ((E_{AMD}−E_{BMD}) (E_{ATD}−E_{BTD})) of a difference (E_{AMD}−E_{BMD}) between a maximum expansion rate E_{AMD} (%) of the support in an MD direction during heating from T1 (° C.) to T2 (° C.) and an expansion rate E_{BMD} (%) of the support at T2 (° C.) at the end of heating and a difference (E_{ATD}−E_{BTD}) between a maximum expansion rate E_{ATD} (%) of the support in a TD direction during heating from T1 (° C.) to T2 (° C.) and an expansion rate E_{BTD} (%) of the support at T2 (° C.) at the end of heating, and Y is a lowest melt viscosity (poise) of the resin composition layer at 120° C. or higher.

2. The method according to claim 1, wherein the printed wiring board satisfies a relation of Y>2700X>300.

3. The method according to claim 1, wherein X is 4 or less.

4. The method according to claim 1, wherein Y is 4,000 poises or more.

5. A method for producing a printed wiring board, comprising:
(A) preparing an adhesive sheet comprising a support and a resin composition layer provided on said support;
(B) laminating said adhesive sheet on an internal layer substrate so that said resin composition layer is in contact with said internal layer substrate; and
(C) thermally curing said adhesive sheet by heating from T1 (° C.) to T2 (° C.), to form an insulating layer, wherein
the adhesive sheet is thermally cured so that a sum ((E_{AMD}−E_{BMD})+(E_{ATD}−E_{BTD})) of a difference (E_{AMD}−E_{BMD}) between a maximum expansion rate E_{AMD} (%) of the support in an MD direction during heating from T1 (° C.) to T2 (° C.) and an expansion rate E_{BMD} (%) of the support at T2 (° C.) at the end of heating and a difference (E_{ATD}−E_{BTD}) between a maximum expansion rate E_{ATD} (%) of the support in a TD direction during heating from T1 (° C.) to T2 (° C.) and an expansion rate E_{BTD} (%) of the support at T2 (° C.) at the end of heating is 4 or less and a lowest melt viscosity of the resin composition layer at T1 (° C.) or higher is 4,000 poises or more.

6. The method according to claim 1, wherein T1 satisfies a relation of 50° C.≦T1≦150° C.

7. The method according to claim 1, wherein T1 satisfies a relation of 120° C.≦T1≦150° C.

8. The method according to claim 1, wherein T2 satisfies a relation of 150° C.≦T2≦240° C.

9. The method to claim 1, wherein thermal curing in the step (C) is performed by heating the adhesive sheet at T1 (° C.) and then at T2 (° C.).

10. The method according to claim 1, wherein the support is a plastic film.

11. A semiconductor device, comprising a printed wiring board produced by a method according to claim 1.

12. The method according to claim 5, wherein T1 satisfies a relation of 50° C.≦T1≦150° C.

13. The method according to claim 5, wherein T1 satisfies a relation of 120° C.≦T1≦150° C.

14. The method according to claim 5, wherein T2 satisfies a relation of 150° C.≦T2≦240° C.

15. The method according to claim 5, wherein thermal curing in the step (C) is performed by heating the adhesive sheet at T1 (° C.) and then at T2 (° C.).

16. The method according to claim 5, wherein the support is a plastic film.

17. A semiconductor device, comprising a printed wiring board produced by a method according to claim 5.

18. A layered body, comprising:
an internal layer substrate;
an insulating layer provided on said internal layer substrate; and
a support being in contact with said insulating layer, wherein
variation in a thickness of the insulating layer is 1 μm or less in a region except for 5% of a dimension of the support from edge portions of the support.

19. An adhesive sheet, comprising a support and a resin composition layer provided on the support, wherein
during thermal curing by heating the adhesive sheet from T1 (° C.) to T2 (° C.), the adhesive sheet satisfies a relation of Y>2700X, wherein X is a sum ((E_{AMD}−E_{BMD})+(E_{ATD}−E_{BTD})) of a difference (E_{AMD}−E_{BMD}) between a maximum expansion rate E_{AMD} (%) of the support in an MD direction during heating from T1 (° C.) to T2 (° C.) and an expansion rate E_{BMD} (%) of the support at T2 (° C.) at the end of heating and a difference (E_{ATD}−E_{BTD}) between a maximum expansion rate E_{ATD} (%) of the support in a TD direction during heating from T1 (° C.) to T2 (° C.) and an expansion rate E_{BTD} (%) of the support at T2 (° C.) at the end of heating, and Y is a lowest melt viscosity (poise) of the resin composition layer at 120° C. or higher.
